(19) United States
(12) Patent Application Publication
(10) Pub. No.: US 2026/0331890 A1
(43) Pub. Date: Oct. 22, 2026

(54) ELECTRICAL CONNECTION UNIT

(71) Applicant: YAZAKI CORPORATION, Tokyo (JP)

(72) Inventors: Kazutaka Uki, Kakegawa-shi (JP); Yuuki Miyazawa, Kakegawa-shi (JP); Mitsuru Saito, Kakegawa-shi (JP); Tatsuya Shiraishi, Kakegawa-shi (JP)

(21) Appl. No.: 19/466,192

(22) Filed: Jan. 30, 2026

(30) Foreign Application Priority Data
Feb. 3, 2025 (JP) 2025-015993

(51) Int. Cl. H02G 3/16; H02G 3/03; H02G 3/08

(52) U.S. Cl. CPC H02G 3/16; H02G 3/03; H02G 3/081

(57) ABSTRACT

An electrical connection unit includes a base member, a connection target component, a routing member, and a metal member. The base member includes a first support surface. The connection target component includes a metal plate portion that is disposed in an upright posture with respect to the first support surface. The routing member includes a connection portion overlapping the metal plate portion when seen from a first direction, which is a plate thickness direction of the metal plate portion, and is electrically connected to the metal plate portion. The metal member overlaps the metal plate portion when seen from the first direction.

### BACKGROUND OF THE INVENTION

### Field of the Invention

Embodiments of the present invention relate to an electrical connection unit.

Priority is claimed on Japanese Patent Application No. 2025-015993 filed in Japan on February 3, 2025, the content of which is incorporated herein by reference.

### Description of Related Art

An electrical connection unit that includes an electronic component and a routing member that is electrically connected to the electronic component is known.

### CITATION LIST

### Patent Document

Patent Document 1: Japanese Unexamined Patent Application, First Publication No. 2024-037492

### SUMMARY OF THE INVENTION

The electrical connection unit has been expected to have improved thermal characteristics.

An embodiment provides an electrical connection unit capable of improving thermal characteristics.

An electrical connection unit of an embodiment includes a base member, a connection target component, a routing member, and a metal member. The base member includes a first support surface. The connection target component includes a metal plate portion that is disposed in an upright posture with respect to the first support surface. The routing member includes a connection portion overlapping the metal plate portion when seen from a first direction, which is a plate thickness direction of the metal plate portion, and is electrically connected to the metal plate portion. The metal member overlaps the metal plate portion when seen from the first direction.

According to an embodiment, the thermal characteristics of the electrical connection unit can be improved.

### BRIEF DESCRIPTION OF THE DRAWINGS

FIG. 1 is a perspective view illustrating an electrical connection unit of an embodiment in a partially exploded manner.

FIG. 2 is a perspective view illustrating a part of the electrical connection unit of the embodiment.

FIG. 3 is a perspective view for explaining an electronic component of a first type and a heat storage of the embodiment.

FIG. 4 is a perspective view for explaining an electronic component of a second type and a heat storage of the embodiment.

FIG. 5 is a plan view for explaining a heat storage of a first aspect of the embodiment.

FIG. 6 is a sectional view of the structure illustrated in FIG. 5 along the line F6-F6.

FIG. 7 is a sectional view for explaining a first modification of the heat storage of the first aspect of the embodiment.

FIG. 8 is a sectional view for explaining a second modification of the heat storage of the first aspect of the embodiment.

FIG. 9 is a sectional view for explaining a third modification of the heat storage of the first aspect of the embodiment.

FIG. 10 is a sectional view for explaining a fourth modification of the heat storage of the first aspect of the embodiment.

FIG. 11 is a perspective view for explaining a fifth modification of the heat storage of the first aspect of the embodiment.

FIG. 12 is a plan view for explaining a different heat storage of the first aspect of the embodiment.

FIG. 13 is a sectional view of the structure illustrated in FIG. 12 along the line F13-F13.

FIG. 14 is a sectional view for explaining a first modification of the different heat storage of the first aspect of the embodiment.

FIG. 15 is a sectional view for explaining a second modification of the different heat storage of the first aspect of the embodiment.

FIG. 16 is a sectional view for explaining a third modification of the different heat storage of the first aspect of the embodiment.

FIG. 17 is a sectional view for explaining a fourth modification of the different heat storage of the first aspect of the embodiment.

FIG. 18 is a perspective view illustrating a part of an electrical connection unit corresponding to a second aspect of the embodiment.

FIG. 19 is a perspective view for explaining a heat storage of the second aspect of the embodiment.

FIG. 20 is a plan view for explaining the heat storage of the second aspect of the embodiment.

FIG. 21 is a sectional view of the structure illustrated in FIG. 20 along the line F21-F21.

FIG. 22 is a sectional view of the structure illustrated in FIG. 21 along the line F22-F22.

FIG. 23 is a sectional view for explaining a first modification of the heat storage of the second aspect of the embodiment.

FIG. 24 is a sectional view for explaining a second modification of the heat storage of the second aspect of the embodiment.

FIG. 25 is a perspective view illustrating a part of an electrical connection unit corresponding to a third aspect of the embodiment.

FIG. 26 is a perspective view for explaining a heat storage of the third aspect of the embodiment.

FIG. 27 is a sectional view for explaining the heat storage of the third aspect of the embodiment.

FIG. 28 is a sectional view of the structure illustrated in FIG. 27 along the line F28-F28.

FIG. 29 is a sectional view for explaining a first modification of the heat storage of the third aspect of the embodiment.

FIG. 30 is a perspective view for explaining a second modification of the heat storage of the third aspect of the embodiment.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. Note that the constitution described below does not limit the scope of the embodiments.

In the present disclosure, the terms are defined as follows. The term “connection” is not limited to a mechanical connection and may include an electrical connection. In other words, the term “connection” is not limited to a case where two elements that are connection targets are directly connected, and may include a case where two elements that are connection targets are connected with another element interposed therebetween. The term “facing”, “overlapping”, or “adjacent” indicates that virtual projection images of two target objects overlap each other when seen from a specific direction. For example, the term “facing” or “overlapping” is not limited to a case where two target objects directly face each other, and may include a case where two target objects face each other in a state in which another member or a gap exists between the two target objects. In addition, “facing” or “overlapping” is not limited to a case of completely overlapping when seen from the specific direction, and may include a case of at least partially overlapping. “Adjacent” is not limited to a case where two target objects are adjacent to each other, and may include a case where two target objects are aligned in a state in which another member or a gap exists between the two target objects. “Parallel”, “orthogonal”, or “the same” may include “substantially parallel”, “substantially orthogonal”, or “substantially the same”, respectively.

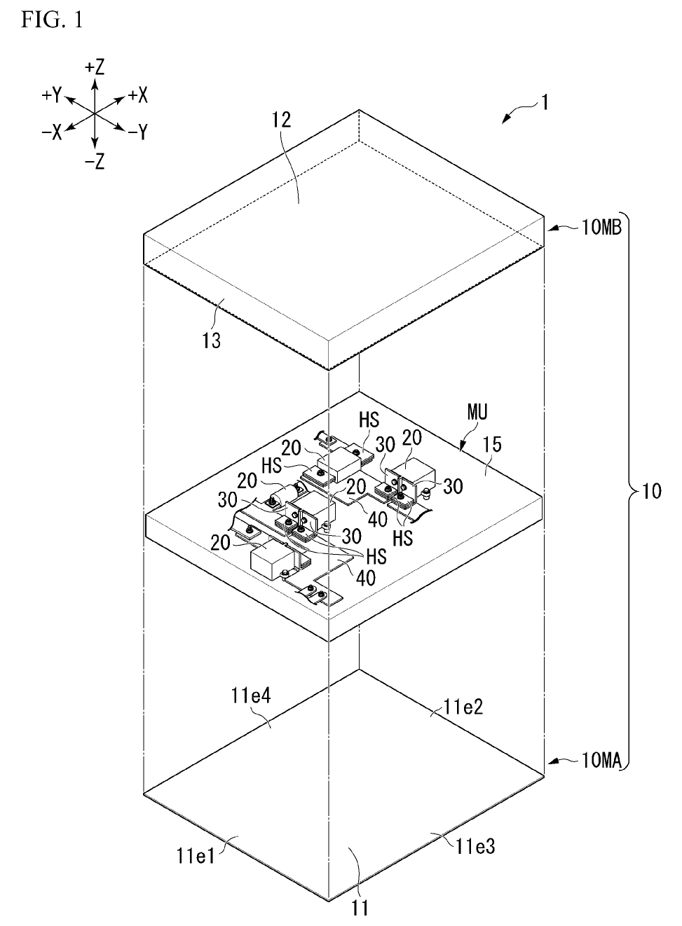

In the present disclosure, a +X direction, a -X direction, a +Y direction, a -Y direction, a +Z direction, and a -Z direction are defined as follows. The +X direction is a direction from a first end portion 11e1 to a second end portion 11e2 of a lower wall 11 of a housing 10, which will be described later, for example (see FIG. 1). The -X direction is a direction opposite to the +X direction. Hereinafter, in a case where the +X direction and the -X direction are not distinguished, the directions will be simply referred to as an “X direction”. The +Y direction and the -Y direction are directions intersecting (for example, orthogonal to) the X direction. The +Y direction is a direction from a third end portion 11e3 to a fourth end portion 11e4 of the lower wall 11 of the housing 10, which will be described later, for example (see FIG. 1). The -Y direction is a direction opposite to the +Y direction. Hereinafter, in a case where the +Y direction and the -Y direction are not distinguished, the directions will be simply referred to as a “Y direction”. The +Z direction and the -Z direction are directions intersecting (for example, orthogonal to) the X direction and the Y direction. The +Z direction is a direction from the lower wall 11 of the housing 10, which will be described later, to a main body MU (see FIG. 1). The -Z direction is a direction opposite to the +Z direction. Hereinafter, in a case where the +Z direction and the -Z direction are not distinguished, the directions will be simply referred to as a “Z direction”.

Hereinafter, in a case where the X direction and the Y direction are not distinguished, the directions may be referred to as a “horizontal direction”. Hereinafter, the Z direction may be referred to as a “vertical direction”. Hereinafter, the +Z direction side may be referred to as an “upper” side, and the -Z direction side may be referred to as a “lower” side. However, these expressions are expressions for convenience of description, and do not limit a gravity direction of an electrical connection unit 1 (an installation posture of the electrical connection unit 1).

### EMBODIMENTS

### 1. Configuration of Electrical Connection Unit

FIG. 1 is a perspective view illustrating the electrical connection unit 1 of an embodiment in a partially exploded manner. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit1 is not limited to a box-shaped device. The electrical connection unit 1 includes, for example, the housing 10 and the main body MU.

### Housing

The housing 10 is a member forming the exterior of the electrical connection unit 1. The housing 10 has, for example, a flat box shape. The housing 10 is made of, for example, a synthetic resin and has an insulating property. The housing 10 accommodates the main body MU. The housing 10 includes, for example, the lower wall 11 (first wall portion), an upper wall 12 (second wall portion), and a peripheral wall 13 (third wall portion). The lower wall 11 covers at least a part of the main body MU from the lower side (-Z direction side). The upper wall 12 covers at least a part of the main body MU from the upper side (+Z direction side). The peripheral wall 13 surrounds the periphery of the main body MU.

The housing 10 includes, for example, a first member 10MA including the lower wall 11 and a second member 10MB including the upper wall 12 and the peripheral wall 13. In the present embodiment, the housing 10 is formed by the first member 10MA and the second member 10MB being combined. Note that the lower wall 11 may be formed of an insulating sheet or the like instead of the wall having rigidity. A part or entirety of the housing 10 may be omitted.

### Main Body

The main body MU is a part that performs a main function (for example, switching of electrical connection states or overcurrent protection) of the electrical connection unit 1. The main body MU may be referred to as a “circuit constitution body”. The main body MU includes, for example, a base member 15, a plurality of electronic components 20, a plurality of connection components 30, a plurality of bus bars 40, and a plurality of heat storages HS.

### 2. Base Member

First, the base member 15 will be described. The base member 15 is a member that supports one or more electronic components 20 and/or one or more bus bars 40 inside the housing 10. The base member 15 is made of, for example, a synthetic resin and has an insulating property. The base member 15 is disposed between where the electronic components 20 and the bus bars 40 are provided and the lower wall 11 of the housing 10 in the Z direction. The base member 15 is fixed to, for example, the lower wall 11 of the housing 10. The base member 15 supports the one or more electronic components 20 and/or the one or more bus bars 40 from the lower side. The base member 15 may be a wall portion along the horizontal direction, a structure in which a plurality of ribs standing in the vertical direction are combined, or the like. The base member 15 may be formed by a part of the housing 10.

### 3. Electronic Component

Next, each electronic component 20 will be described. The electronic component 20 is an electronic component mounted in accordance with a function required for the main body MU. The electronic component 20 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. However, the type of the electronic component 20 is not limited to the above example. The electronic component 20 is, for example, a heat generating component that generates heat at the time of energization.

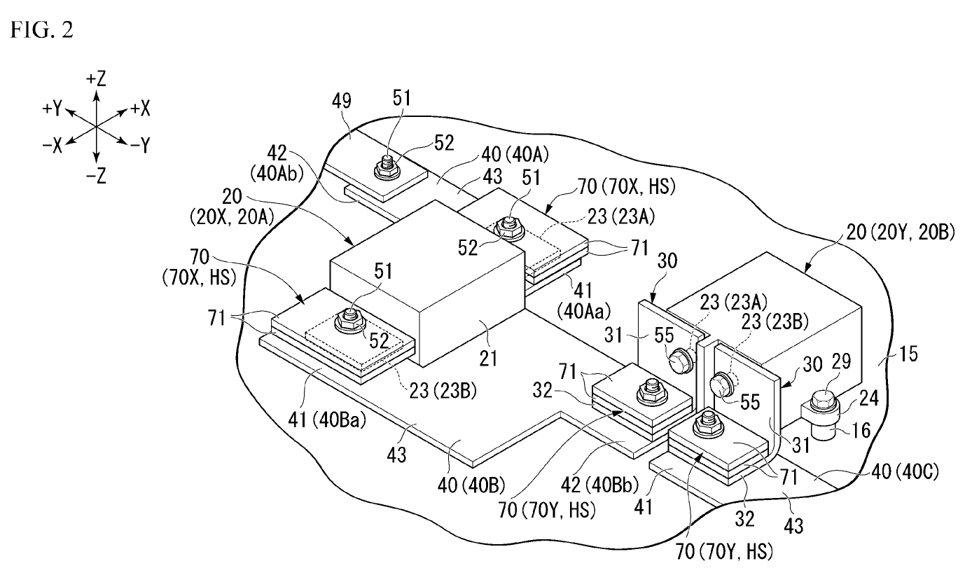

FIG. 2 is a perspective view illustrating a part of the electrical connection unit 1. In the present embodiment, an electronic component 20X of a first type and an electronic component 20Y as a second type, for example, are provided as the electronic components 20. Note that the electrical connection unit 1 does not need to include both the electronic component 20X and the electronic component 20Y and may include only one of the electronic component 20X and the electronic component 20Y. Hereinafter, in a case where the electronic component 20X and the electronic component 20Y are not distinguished, the electronic components will be simply referred to as an “electronic component 20”. The electronic component 20 is an example of a “connection target component”.

### 3.1 Electronic Component of First Type

First, the electronic component 20X of the first type will be described.

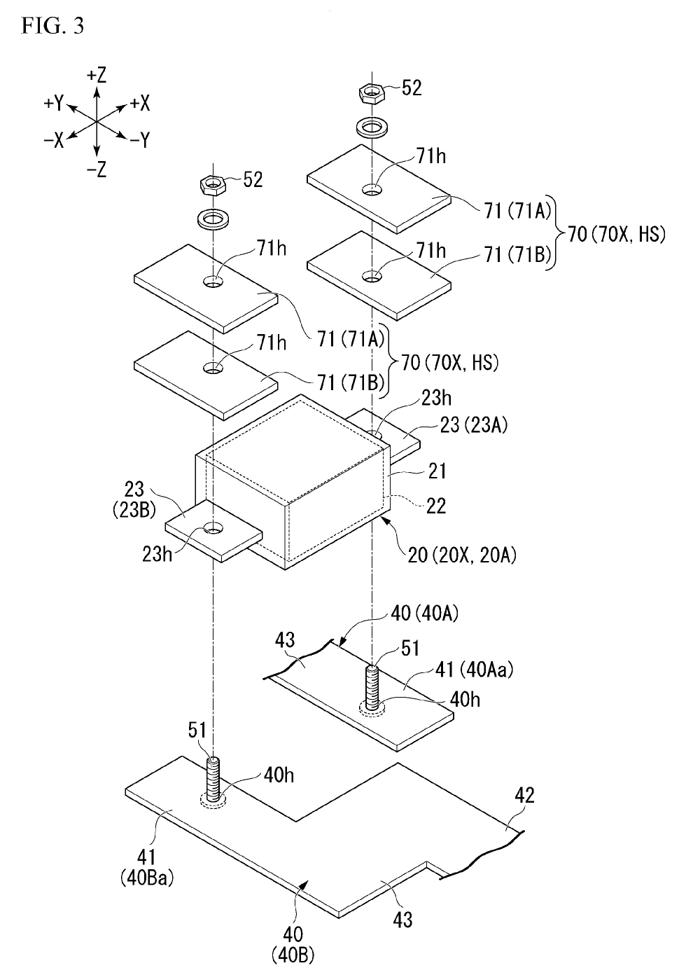

FIG. 3 is a perspective view for explaining the electronic component 20X of the first type and a heat storage HS corresponding to the electronic component 20X. The electronic component 20X includes, for example, a case 21, a component main body 22, and a plurality of terminals 23.

### Case

The case 21 is an exterior member that forms a most part of the exterior of the electronic component 20. The case 21 is made of, for example, a synthetic resin and has an insulating property. The case 21 accommodates the component main body 22. Note that the case 21 and the component main body 22 may be integrally formed.

### Component Main Body

The component main body 22 is a part that performs a main function of the electronic component 20. In a case where the electronic component 20 is a relay, for example, the component main body 22 includes a switch (for example, a contact) that switches between a conductive state and a non-conductive state. In a case where the electronic component 20 is a fuse, for example, the component main body 22 includes a fusible portion that is fused when an overcurrent flows therethrough. In a case where the electronic component 20 is a capacitor, for example, the component main body 22 includes a part that accumulates an electric charge.

### Terminal

Each of the terminals 23 is an electrical connection portion exposed to the outside of the case 21. The terminal 23 is electrically connected to the component main body 22 inside the case 21. The terminal 23 is made of metal, for example, and is formed in a plate shape along the horizontal direction. The plate thickness direction of the terminal 23 is the Z direction. The terminal 23 is an example of a “metal plate portion”.

The electronic component 20 includes, as the plurality of terminals 23, a terminal 23A and a terminal 23B. One of the terminal 23A and the terminal 23B is a terminal on the positive electrode side. The other one of the terminal 23A and the terminal 23B is a terminal on the negative electrode side. One of the terminal 23A and the terminal 23B is an example of a “first terminal”. The other one of the terminal 23A and the terminal 23B is an example of a “second terminal”.

In the electronic component 20X of the first aspect, the plurality of terminals 23 are disposed in a divided manner at both end portions of the electronic component 20X in the horizontal direction. For example, the terminal 23A and the terminal 23B are disposed in a divided manner at both end portions of the electronic component 20X in the X direction. Each terminal 23 has an attachment hole 23h into which a fastening member 51 (for example, a screw or a bolt), which will be described later, is inserted. The attachment hole 23h is a through-hole penetrating through the terminal 23 in the Z direction. The attachment hole 23h is an example of a “first attachment hole”.

### 3.2 Electronic Component of Second Type

Next, the electronic component 20Y of the second type will be described.

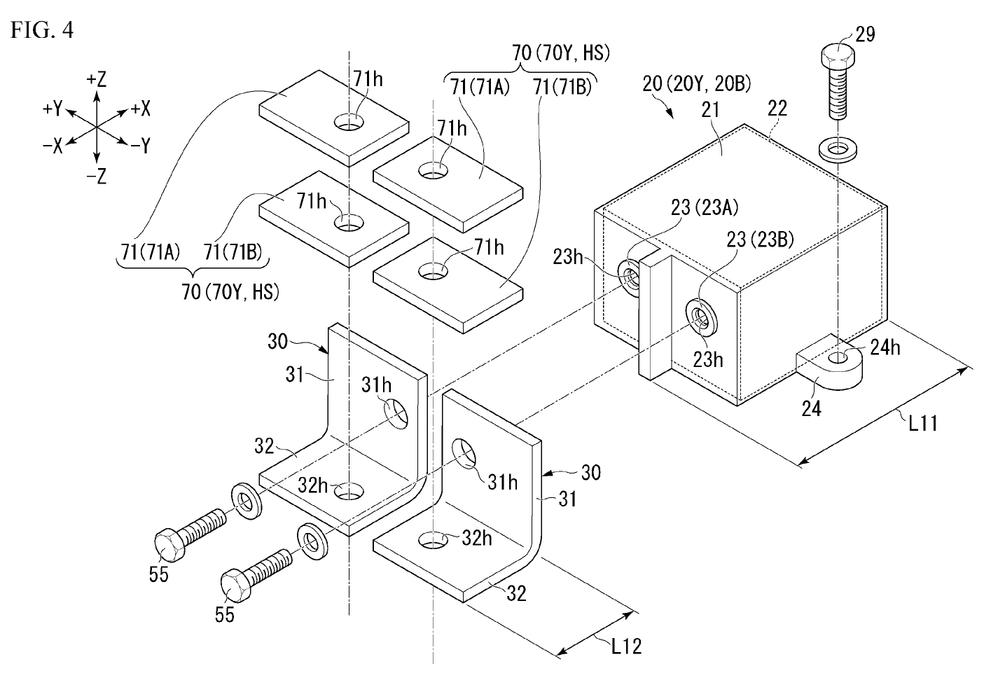

FIG. 4 is a perspective view for explaining the electronic component 20Y of the second type and a heat storage HS corresponding to the electronic component 20Y. The electronic component 20Y includes, for example, a case 21, a component main body 22, a plurality of terminals 23, and an attachment portion 24. Since the case 21 and the component main body 22 of the electronic component 20Y are similar to the case 21 and the component main body 22 of the electronic component 20X described above, repeated description will be omitted.

### Terminal

A terminal 23A and a terminal 23B of the electronic component 20Y are provided at one end portion of the electronic component 20Y in the horizontal direction (for example, the X direction). The terminal 23A and the terminal 23B are disposed to be arranged in the horizontal direction (for example, the Y direction). Each of the terminal 23A and the terminal 23B is directed in the horizontal direction (for example, the X direction).

Each terminal 23 has an attachment hole 23h into which a fastening member 55 (for example, a screw or a bolt), which will be described later, is inserted. The attachment hole 23h is opened in the horizontal direction (for example, the -X direction). In the present embodiment, a fastening member 55 is inserted into the attachment hole 23h from the X direction (for example, from the -X direction side). An inner circumferential surface of the attachment hole 23h of the electronic component 20Y has a screw groove. The attachment hole 23h of the electronic component 20Y is a bottomed engagement hole provided in the electronic component 20Y, for example.

### Attachment Portion

The attachment portion 24 is a part for fixing the electronic component 20Y. The attachment portion 24 is caused to overlap a fixing portion 16 (for example, a boss; see FIG. 2) provided in the base member 15, for example, from the Z direction. The attachment portion 24 includes an attachment hole 24h into which a fastening member 29 (for example, a screw or a bolt) is inserted. The attachment hole 24h is opened in the Z direction. The attachment portion 24 is attached to the base member 15 by the fastening member 29 inserted into the attachment hole 24h being fixed to the fixing portion 16 of the base member 15. The electronic component 20Y is fixed to the base member 15 by the attachment portion 24 being attached to the base member 15.

### 4. Connection Component

Next, the connection components 30 will be described. Each connection component 30 is a component that is disposed between the electronic component 20Y and the bus bar 40 and electrically connects the electronic component 20Y to the bus bar 40. The connection component 30 forms a part of an energization path in the electrical connection unit 1. The connection component 30 is a metal member formed of, for example, copper, a copper alloy, aluminum, or an aluminum alloy. In the present embodiment, a length L12 of the connection component 30 in the longitudinal direction (for example, the X direction) of the electronic component 20Y is shorter than a length L11 of the electronic component 20Y in the longitudinal direction. The connection component 30 is an example of a “connection target component”. The connection component 30 includes, for example, a first part 31 and a second part 32.

### First Part

The first part 31 of the connection component 30 is a part connected to the terminal 23 of the electronic component 20Y. The first part 31 extends in the Z direction along one end portion (for example, the end portion in the -X direction) of the electronic component 20Y. The first part 31 is a plate portion along the Z direction and the Y direction. The first part 31 is a standing portion that stands in the Z direction with respect to the bus bar 40. The first part 31 is adjacent to the electronic component 20Y in the horizontal direction (for example, the X direction). For example, the first part 31 is adjacent to the terminal 23 of the electronic component 20Y in the horizontal direction (for example, the X direction) and is connected to the terminal 23 of the electronic component 20Y from the horizontal direction (for example, the X direction).

The first part 31 of the connection component 30 has an attachment hole 31h into which the fastening member 55 (for example, a screw or a bolt) is inserted. The attachment hole 31h is opened in the horizontal direction (for example, the X direction). The attachment hole 31h faces the attachment hole 23h of the terminal 23 of the electronic component 20Y. The first part 31 is physically and electrically connected to the terminal 23 of the electronic component 20Y by the fastening member 55 inserted into the attachment hole 31h being engaged with the attachment hole 23h of the terminal 23 of the electronic component 20Y.

### Second Part

The second part 32 of the connection component 30 is a part connected to the bus bar 40 (see FIG. 2), which will be described later. The second part 32 is bent in the horizontal direction (for example, the -X direction) from the end portion of the first part 31 on the -Z direction side and extends along the horizontal direction. The second part 32 is a plate portion along the X direction and the Y direction. The second part 32 is adjacent to the bus bar 40 in the Z direction and is connected to the bus bar 40 from the Z direction. The second part 32 of the connection component 30 is an example of a “metal plate portion”.

The second part 32 of the connection component 30 includes an attachment hole 32h into which the fastening member 51 to be described later is inserted. The attachment hole 32h is a through-hole penetrating through the second part 32 in the Z direction. The second part 32 is fixed to the bus bar 40 by an engagement member 52 (for example, a nut; see FIG. 2) being engaged with a tip end portion of the fastening member 51 inserted into the attachment hole 32h. The attachment hole 32h is an example of a “first attachment hole”. In the present embodiment, the first part 31 and the second part 32 form one L-shaped connection component 30.

Note that the expression “the connection component is disposed between the electronic component and the routing member” in the present disclosure is not limited to a case where a part of the connection component is located between the electronic component and the routing member (for example, the bus bar) when seen from the X direction or the Y direction. The expression “the connection component is disposed between the electronic component and the routing member” also includes a case where a part of the connection component is located between the electronic component and the routing member (for example, the bus bar) when seen from a direction inclined with respect to the X direction or the Y direction.

### 5. Bus Bar

Next, returning to FIG. 2, the bus bars 40 will be described. The bus bars 40 are members that form an energization path in the electrical connection unit 1. The bus bars 40 extend among a plurality of connection target components and electrically connect the plurality of connection target components. The "connection target components” include, for example, the electronic components 20, the connection components 30, or bus bars 49 for external connection. However, the connection target components are not limited to the above examples. The connection target components may be the bus bars included in the electrical connection unit. The bus bars 40 are formed of metal members (for example, metal plate materials) such as copper, a copper alloy, aluminum, or an aluminum alloy, for example. The bus bars 40 are an example of a “routing member”.

In the present embodiment, the bus bars 40 are formed in a plate shape along the horizontal direction. The bus bars 40 extend in the X direction or the Y direction. Each bus bar 40 includes a first connection portion 41, a second connection portion 42, and an extending portion 43. In the present embodiment, each of the first connection portion 41, the second connection portion 42, and the extending portion 43 has a plate shape along the horizontal direction.

The first connection portion 41 overlaps at least a part of one connection target component (first connection target component) when seen from the plate thickness direction (for example, the Z direction) of the first connection portion 41. The first connection portion 41 is electrically connected to the first connection target component. The first connection portion 41 is a part that includes a part of the bus bar 40 overlapping at least a part of the first connection target component and extends continuously in a specific direction. The first connection portion 41 includes, for example, a part overlapping the heat storage HS, which will be described later.

The second connection portion 42 overlaps at least a part of a different connection target component (second connection target component) when seen from the plate thickness direction (for example, the Z direction) of the second connection portion 42. The second connection portion 42 is electrically connected to the second connection target component. The second connection portion 42 is a part that includes a part of the bus bar 40 overlapping at least a part of the second connection target component and extends continuously in a specific direction. The second connection portion 42 includes, for example, a part overlapping the heat storage HS, which will be described later.

The extending portion 43 is provided between the first connection portion 41 and the second connection portion 42 and extends to connect the first connection portion 41 to the second connection portion 42.

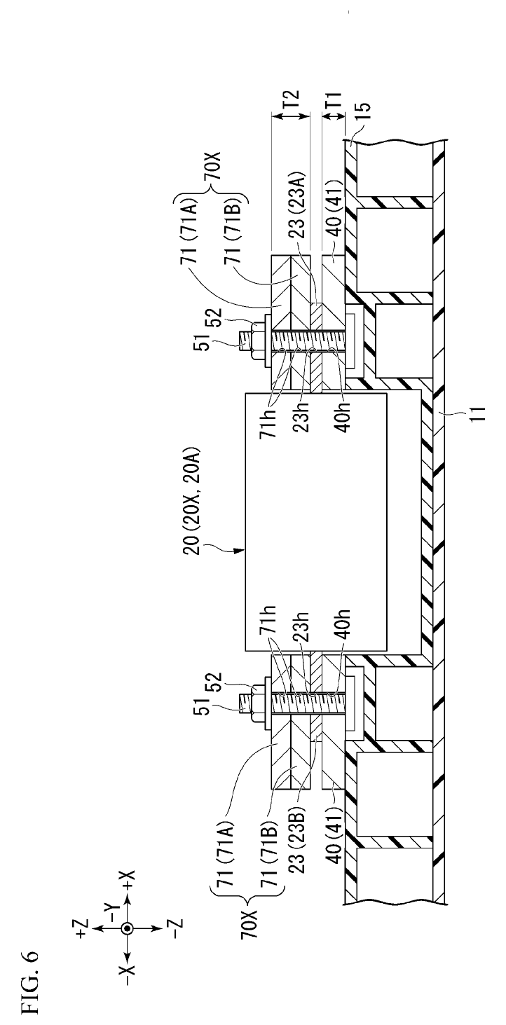

In the present embodiment, the fastening member 51 is attached to each of the first connection portion 41 and the second connection portion 42 (see FIGS. 2 and 3). The fastening member 51 is, for example, a rivet bolt fixed to the bus bar 40. In the present embodiment, each of the first connection portion 41 and the second connection portion 42 includes an attachment hole 40h (see FIG. 6). The attachment hole 40h is a through-hole penetrating through the bus bar 40 in the Z direction. The fastening member 51 is inserted into the attachment hole 40h of the bus bar 40 and projects on the +Z direction side from the first connection portion 41 or the second connection portion 42. Note that the fastening member 51 is not limited to a rivet bolt and may be a general bolt, a screw, or the like. The attachment hole 40h is an example of a “second attachment hole”.

As illustrated in FIG. 2, the plurality of electronic components 20 include an electronic component 20A and an electronic component 20B in the present embodiment. The electronic component 20A is, for example, the aforementioned electronic component 20X of the first type. The electronic component 20B is, for example, the aforementioned electronic component 20Y of the second aspect. However, the types of the electronic components 20A and 20B are not limited to those of the aforementioned example. In the present embodiment, the plurality of bus bars 40 include a bus bar 40A, a bus bar 40B, and a bus bar 40C.

A first connection portion 41 of the bus bar 40A is located at a first end portion 40Aa of the bus bar 40A, for example. The first connection portion 41 of the bus bar 40A overlaps a terminal 23A of the electronic component 20A when seen from the Z direction. An attachment hole 40h of the first connection portion 41 of the bus bar 40A faces an attachment hole 23h of the terminal 23A of the electronic component 20A in the Z direction. The fastening member 51 inserted into the attachment hole 40h of the first connection portion 41 of the bus bar 40A is inserted into the attachment hole 23h of the terminal 23A of the electronic component 20A. For example, the first connection portion 41 of the bus bar 40A is physically and electrically connected to the terminal 23A of the electronic component 20A by the engagement member 52 being engaged with the tip end portion of the fastening member 51 inserted into the attachment hole 40h of the first connection portion 41 and the attachment hole 23h of the terminal 23A.

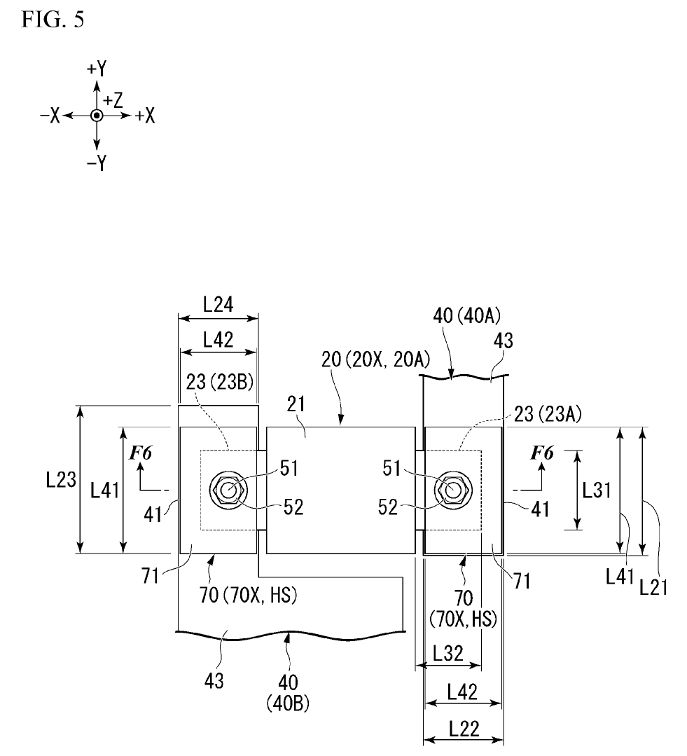

In the present embodiment, the first connection portion 41 of the bus bar 40A (for example, the first end portion 40Aa of the bus bar 40A) extends linearly in the Y direction. A length L21 of the first connection portion 41 of the bus bar 40A (for example, the first end portion 40Aa of the bus bar 40A) in the Y direction is longer than a length L22 of the first connection portion 41 of the bus bar 40A (for example, the first end portion 40Aa of the bus bar 40A) in the X direction (see FIG. 5). However, the shape of the bus bar 40A is not limited to that of the above example.

A second connection portion 42 of the bus bar 40A is located at a second end portion 40Ab of the bus bar 40A, for example. The second connection portion 42 of the bus bar 40A overlaps the bus bar 49 for external connection, for example, when seen from the Z direction. The second connection portion 42 of the bus bar 40A is physically and electrically connected to the bus bar 49 for external connection.

A first connection portion 41 of the bus bar 40B is located at a first end portion 40Ba of the bus bar 40B, for example. The first connection portion 41 of the bus bar 40B overlaps a terminal 23B of the electronic component 20A when seen from the Z direction. The attachment hole 40h of the first connection portion 41 of the bus bar 40A faces an attachment hole 23h of the terminal 23B of the electronic component 20A in the Z direction. The fastening member 51 inserted into the attachment hole 40h of the first connection portion 41 is inserted into the attachment hole 23h of the terminal 23B of the electronic component 20A. For example, the first connection portion 41 of the bus bar 40B is physically and electrically connected to the terminal 23B of the electronic component 20A by an engagement member 52 (for example, a nut) being engaged with the tip end portion of the fastening member 51 inserted into the attachment hole 40h of the first connection portion 41 and the attachment hole 23h of the terminal 23A.

In the present embodiment, the first connection portion 41 of the bus bar 40B (for example, the first end portion 40Ba of the bus bar 40B) extends linearly in the Y direction. A length L23 of the first connection portion 41 of the bus bar 40B (for example, the first end portion 40Ba of the bus bar 40B) in the Y direction is longer than a length L24 of the first connection portion 41 of the bus bar 40B (for example, the first end portion 40Ba of the bus bar 40B) in the X direction (see FIG. 5). However, the shape of the bus bar 40B is not limited to that of the above example.

A second connection portion 42 of the bus bar 40B is located at a second end portion 40Bb of the bus bar 40B, for example. The second connection portion 42 of the bus bar 40B overlaps the connection component 30 corresponding to a terminal 23A of the electronic component 20B when seen from the Z direction. An attachment hole 40h of the second connection portion 42 of the bus bar 40B faces the attachment hole 32h of the second part 32 of the connection component 30 in the Z direction. The second connection portion 42 of the bus bar 40B is connected to the connection component 50 by the fastening member 51 and the engagement member 52 as described above and is electrically connected to the terminal 23A of the electronic component 20B via the connection component 50.

A first connection portion 41 of the bus bar 40C overlaps the connection component 30 corresponding to the terminal 23B of the electronic component 20B when seen from the Z direction. An attachment hole 40h of the first connection portion 41 of the bus bar 40C faces the attachment hole 32h of the second part 32 of the connection component 30 in the Z direction. The first connection portion 41 of the bus bar 40C is connected to the connection component 30 by the fastening member 51 and the engagement member 52 as described above and is electrically connected to the terminal 23B of the electronic component 20B via the connection component 30.

### 6. Heat Storage

Next, the heat storages HS will be described.

The heat storages HS are metal portions that raise a heat storage property (heat absorbing property) of the electrical connection unit 1 by increasing the heat capacity of the electrical connection unit 1. The electrical connection unit 1 includes, as the heat storages HS, one or more of a heat storage 70 of a first aspect, a heat storage 80 of a second aspect, and a heat storage 80' of a third aspect. Note that the electrical connection unit 1 is not required to include all of the heat storages 70, 80, and 80' and may include only any one of the heat storage 70, the heat storage 80, and the heat storage 80'. Hereinafter, these heat storages 70, 80, and 80' will be described in order.

### 7. Heat Storage of First Aspect

First, the heat storage 70 of the first aspect will be described with reference to FIG. 2. The heat storage 70 of the first aspect is a heat storage formed by one or more metal plates 71. The electrical connection unit 1 of the present embodiment includes, as the plurality of heat storages 70, a heat storage 70X corresponding to the aforementioned electronic component 20X of the first type and a heat storage 70Y corresponding to the aforementioned electronic component 20Y of the second aspect. However, the electrical connection unit 1 is not required to include both the heat storage 70X and the heat storage 70Y and may include only one of the heat storage 70X and the heat storage 70Y.

### 7.1 Heat Storage Corresponding to Electronic Component of First Type

Next, the heat storage 70X corresponding to the electronic component 20X of the first type will be described with reference to FIG. 3. The heat storage 70X is provided for the terminal 23 of the electronic component 20X. The heat storage 70X includes one or more metal plates 71. Each of the one or more metal plates 71 overlaps the terminal 23 of the electronic component 20X when seen from the Z direction.

In the present embodiment, the heat storage 70X includes a first metal plate 71A and a second metal plate 71B that are the plurality of (for example, two) metal plates 71. Each of the first metal plate 71A and the second metal plate 71B overlaps the terminal 23 of the electronic component 20X when seen from the Z direction. The heat storage 70X is formed by the plurality of (for example, two) metal plates 71 being disposed in an overlapping manner in the Z direction. Note that the heat storage 70X may be formed by one metal plate 71 or may be formed by three or more metal plates 71. Each metal plate 71 is a plate member along the horizontal direction. Each metal plate 71 has, for example, a rectangular shape when seen from the Z direction. The metal plates 71 are formed of a material such as copper, a copper alloy, aluminum, or an aluminum alloy, for example.

Each metal plate 71 is disposed in parallel with the terminal 23 of the electronic component 20A. Each metal plate 71 overlaps the terminal 23 of the electronic component 20A when seen from the Z direction. Each metal plate 71 includes an attachment hole 71h. The attachment hole 71h is a through-hole penetrating through the metal plate 71 in the Z direction. The attachment hole 71h faces the attachment hole 23h of the terminal 23 of the electronic component 20A when seen from the Z direction. The attachment hole 71h is an example of a “third attachment hole”.

In the present embodiment, the fastening member 51 inserted into the attachment hole 40h of the bus bar 40 and the attachment hole 23h of the terminal 23 of the electronic component 20A is inserted into the attachment holes 71h of the plurality of (for example, two) metal plates 71. Then, the engagement member 52 is engaged with the tip end portion of the fastening member 51 inserted into the attachment hole 40h of the bus bar 40, the attachment hole 23h of the terminal 23 of the electronic component 20A, and the attachment holes 71h of the plurality of (for example, two) metal plates 71. With this configuration, the terminal 23 of the electronic component 20A, the bus bar 40, and the plurality of (for example, two) metal plates 71 are fixed by the fastening member 51. In the present embodiment, the terminal 23 of the electronic component 20A, the bus bar 40, and the plurality of (for example, two) metal plates 71 are fastened together using the fastening member 51.

FIG. 5 is a plan view for explaining the heat storage 70X. In the present embodiment, the plurality of metal plates 71 have the same size and the same shape when seen from the Z direction. Each metal plate 71 is larger than the terminal 23 of the electronic component 20A when seen from the Z direction. For example, a length L41 of each metal plate 71 in the Y direction is longer than a length L31 of the terminal 23 of the electronic component 20A in the Y direction. A length L42 of each metal plate 71 in the X direction is longer than a length L32 of the terminal 23 of the electronic component 20A in the X direction.

In the present embodiment, the length L41 of the metal plate 71 in the Y direction is longer than a length L42 of the metal plate 71 in the X direction. In other words, the metal plate 71 overlapping the terminal 23A of the electronic component 20A extends in the Y direction, which is the longitudinal direction of the first connection portion 41 of the bus bar 40A. For example, a length L21 of the first connection portion 41 of the bus bar 40A in the Y direction is equal to or greater than the length L41 of the metal plate 71 in the Y direction. A length L22 of the first connection portion 41 of the bus bar 40A in the X direction is equal to or greater than the length L42 of the metal plate 71 in the X direction, for example.

Similarly, the metal plate 71 overlapping the terminal 23B of the electronic component 20A extends in the Y direction, which is the longitudinal direction of the first connection portion 41 of the bus bar 40B. For example, a length L23 of the first connection portion 41 of the bus bar 40B in the Y direction is equal to or greater than the length L41 of the metal plate 71 in the Y direction. A length L24 of the first connection portion 41 of the bus bar 40B in the X direction is equal to or greater than the length L42 of the metal plate 71 in the X direction, for example.

FIG. 6 is a sectional view of the structure illustrated in FIG. 5 along the line F6-F6. In the present embodiment, the plurality of (for example, two) metal plates 71 are disposed on the side opposite to the first connection portion 41 of the bus bar 40 with respect to the terminal 23 of the electronic component 20A. For example, the first connection portion 41 of the bus bar 40 is disposed below the terminal 23 of the electronic component 20A. The first connection portion 41 of the bus bar 40 is disposed between the terminal 23 of the electronic component 20A and the base member 15 in the Z direction. The first connection portion 41 of the bus bar 40 is in contact with the terminal 23 of the electronic component 20A from the lower side. On the other hand, the plurality of (for example, two) metal plates 71 are disposed above the terminal 23 of the electronic component 20A and are exposed to an internal space of the housing 10. One metal plate 71 from among the plurality of metal plates 71 is in contact with the terminal 23 of the electronic component 20A from the upper side.

In the present embodiment, a total thickness T2 (that is, the thickness of the heat storage HS in the Z direction), which is the sum of the thicknesses of the plurality of metal plates 71 in the Z direction, is thicker than a thickness T1 of the first connection portion 41 of the bus bar 40 in the Z direction.

### 7.2 Modifications of Heat Storage Corresponding to Electronic Component of First Type

Some modifications of the heat storage 70X will be described below. Note that configurations other than those described below in each modification are the same as the aforementioned configurations of the heat storage 70X.

### 7.2.1 First Modification

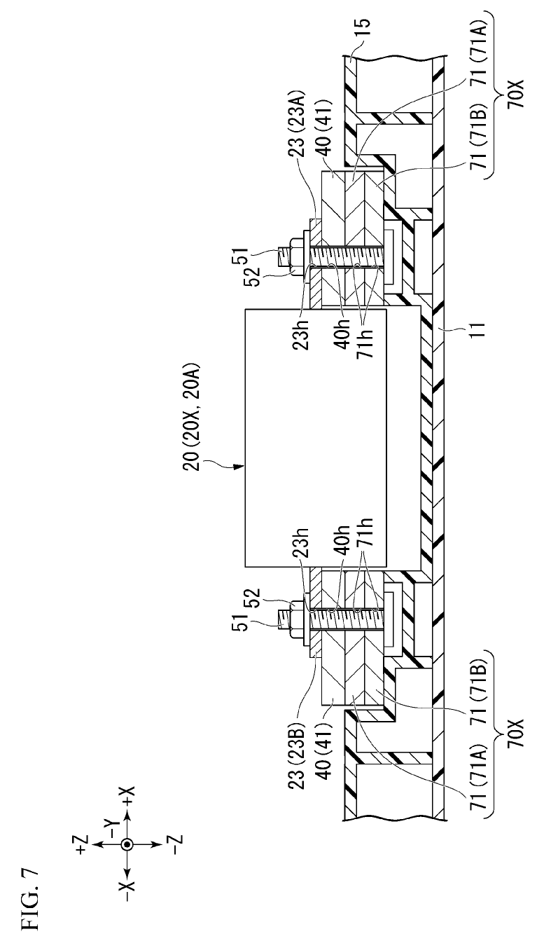

FIG. 7 is a sectional view for explaining the heat storage 70X of a first modification. In the present modification, the plurality of (for example, two) metal plates 71 are disposed on the side opposite to the terminal 23 of the electronic component 20A with respect to the first connection portion 41 of the bus bar 40. For example, the first connection portion 41 of the bus bar 40 is disposed below the terminal 23 of the electronic component 20A and is in contact with the terminal 23 of the electronic component 20A from the lower side. The plurality of (for example, two) metal plates 71 are disposed below the first connection portion 41 of the bus bar 40. The plurality of (for example, two) metal plates 71 are disposed between the first connection portion 41 of the bus bar 40 and the base member 15 in the Z direction. One metal plate 71 from among the plurality of metal plates 71 is in contact with the first connection portion 41 of the bus bar 40 from the lower side.

### 7.2.2 Second Modification

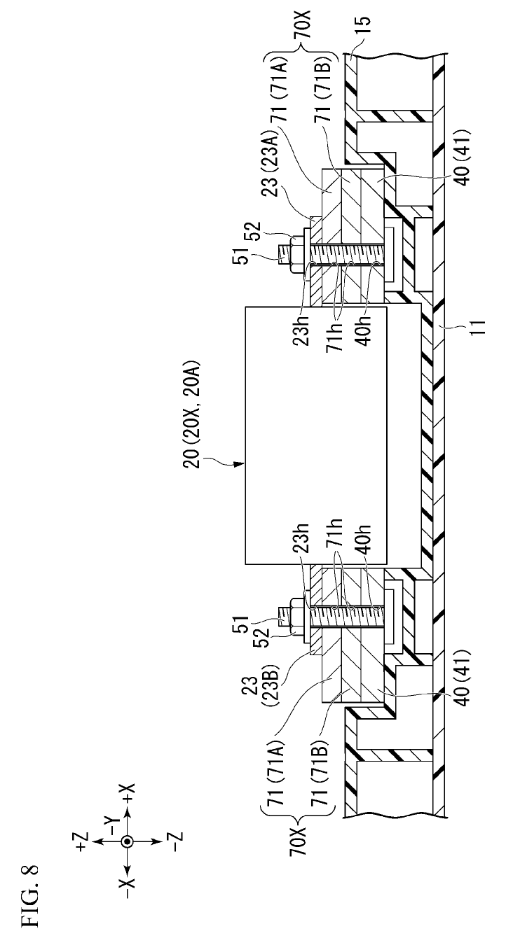

FIG. 8 is a sectional view for explaining the heat storage 70X of a second modification. In the present modification, the plurality of (for example, two) metal plates 71 are disposed between the terminal 23 of the electronic component 20A and the first connection portion 41 of the bus bar 40 in the Z direction. The plurality of (for example, two) metal plates 71 are sandwiched between the terminal 23 of the electronic component 20A and the first connection portion 41 of the bus bar 40 in the Z direction. For example, one metal plate 71 (first metal plate 71A) from among the plurality of metal plates 71 is in contact with the terminal 23 of the electronic component 20A from the lower side. One different metal plate 71 (second metal plate 71B) from among the plurality of metal plates 71 is in contact with the first connection portion 41 of the bus bar 40 from the upper side.

### 7.2.3 Third Modification

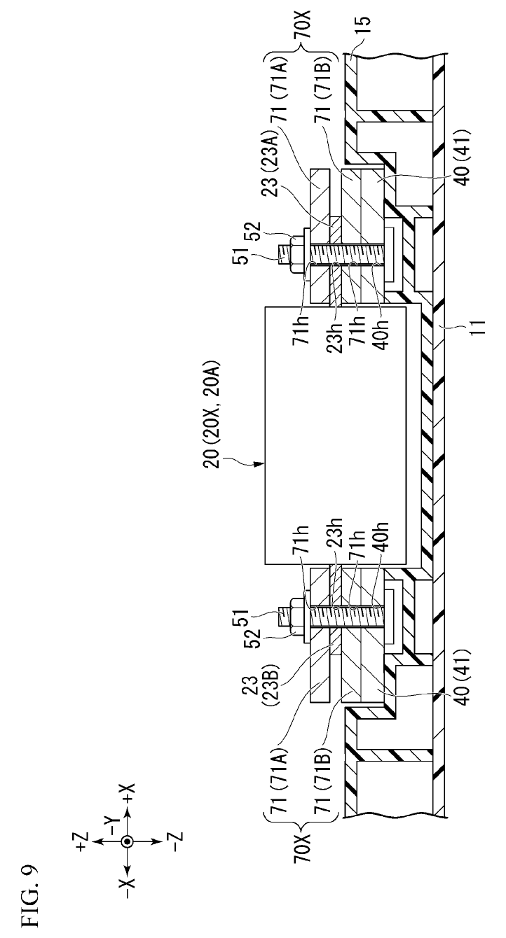

FIG. 9 is a sectional view for explaining the heat storage 70X of a third modification. In the present modification, the plurality of (for example, two) metal plates 71 are disposed in a divided manner on both sides of the terminal 23 of the electronic component 20A in the Z direction. For example, one metal plate 71 (first metal plate 71A) from among the plurality of metal plates 71 is disposed above the terminal 23 of the electronic component 20A and is in contact with the terminal 23 of the electronic component 20A from the upper side. One different metal plate 71 (second metal plate 71B) from among the plurality of metal plates 71 is disposed between the terminal 23 of the electronic component 20A and the first connection portion 41 of the bus bar 40. For example, the second metal plate 71B is sandwiched between the terminal 23 of the electronic component 20A and the first connection portion 41 of the bus bar 40 in the Z direction. The second metal plate 71B is in contact with the terminal 23 of the electronic component 20A from the lower side and is in contact with the first connection portion 41 of the bus bar 40 from the upper side.

### 7.2.4 Fourth Modification

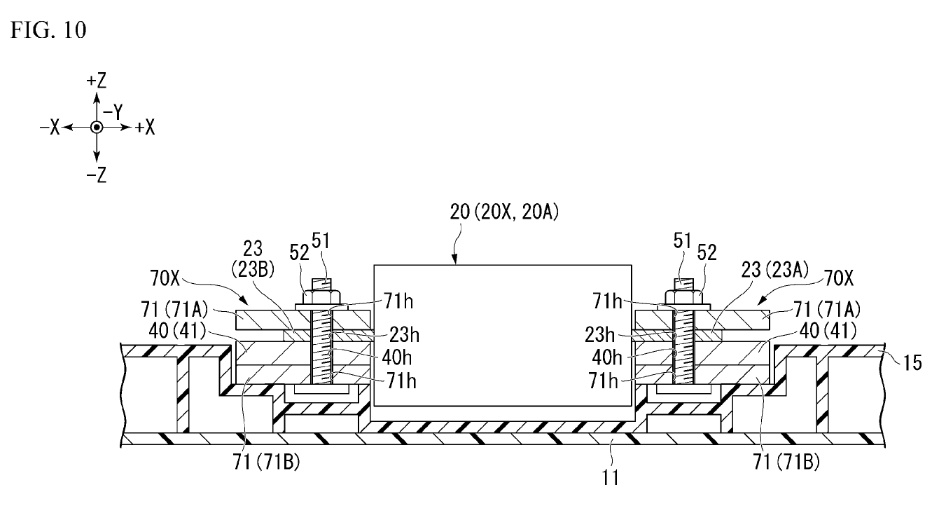

FIG. 10 is a sectional view for explaining the heat storage 70X of a fourth modification. In the present modification, the plurality of (for example, two) metal plates 71 are disposed in a divided manner on both sides of the terminal 23 of the electronic component 20A and the first connection portion 41 of the bus bar 40 in the Z direction. For example, one metal plate 71 (first metal plate 71A) from among the plurality of metal plates 71 is disposed above the terminal 23 of the electronic component 20A and is in contact with the terminal 23 of the electronic component 20A from the upper side. In the present modification, the first connection portion 41 of the bus bar 40 is disposed below the terminal 23 of the electronic component 20A and is in contact with the terminal 23 of the electronic component 20A from the lower side. One different metal plate 71 (second metal plate 71B) from among the plurality of metal plates 71 is disposed below the first connection portion 41 of the bus bar 40 and is in contact with the first connection portion 41 of the bus bar 40 from the lower side. In other words, the first metal plate 71A is disposed on a first side (+Z direction side) in the Z direction with respect to the terminal 23 of the electronic component 20A and the first connection portion 41 of the bus bar 40. On the other hand, the second metal plate 71B is disposed on a second side (-Z direction side), which is the side opposite to the first side in the Z direction with respect to the terminal 23 of the electronic component 20A and the first connection portion 41 of the bus bar 40.

### 7.2.5 Fifth Modification

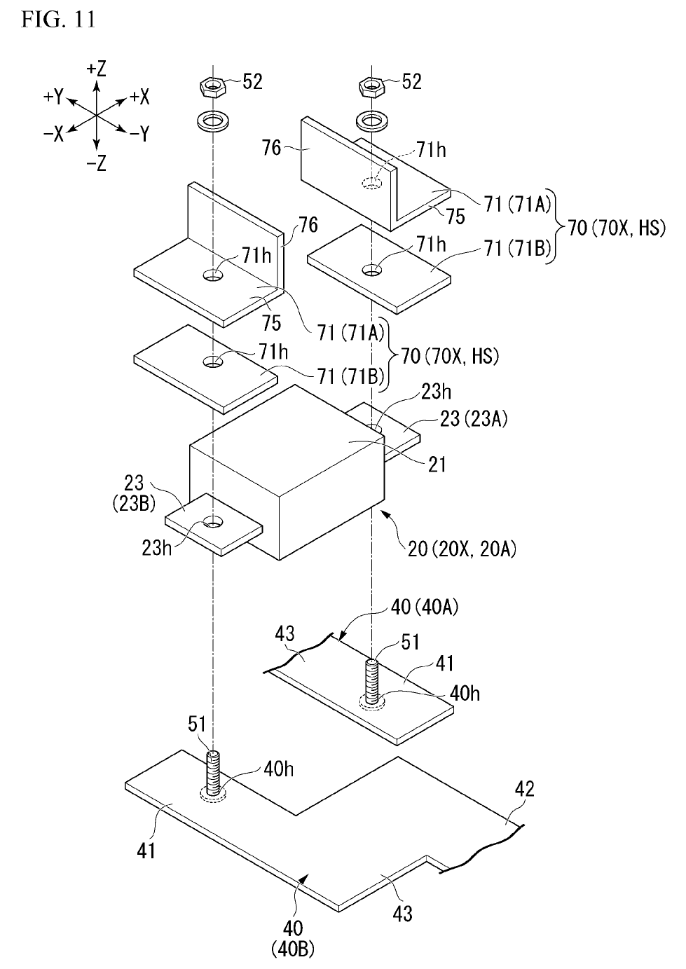

FIG. 11 is a perspective view for explaining the heat storage 70X of a fifth modification. In the present modification, the plurality of metal plates 71 include a first metal plate 71A and a second metal plate 71B. The first metal plate 71A is located on the side opposite to the terminal 23 of the electronic component 20A with respect to the second metal plate 71B. The first metal plate 71A includes a base portion 75 and a bent portion 76. The base portion 75 has a plate shape along the X direction and the Y direction. The base portion 75 is disposed to overlap the second metal plate 71B when seen from the Z direction. The bent portion 76 is formed by being bent in a direction away from the second metal plate 71B (that is, a direction away from the terminal 23 of the electronic component 20A) from the end portion of the base portion 75. With such a configuration, it is possible to increase the heat capacity of the heat storage 70X as compared with the heat storage 70X of the aforementioned embodiment. With this configuration, it is possible to further improve thermal characteristics (for example, a heat storage property and/or a heat dissipation property) of the electrical connection unit 1.

### 7.3 Heat Storage Corresponding to Electronic Component of Second Type

Next, returning to FIG. 4, the heat storage 70Y corresponding to the electronic component 20Y of the second type will be described. The heat storage 70Y is provided for the connection component 30. The heat storage 70Y includes one or more metal plates 71. Each of the one or more metal plates 71 overlaps the second part 32 of the connection component 30 when seen from the Z direction.

In the present embodiment, the heat storage 70Y includes a first metal plate 71A and a second metal plate 71B that are the plurality of (for example, two) metal plates 71. Each of the first metal plate 71A and the second metal plate 71B overlaps the second part 32 of the connection component 30 when seen from the Z direction. The heat storage 70Y is formed by the plurality of (for example, two) metal plates 71 being disposed in an overlapping manner in the Z direction. Note that the heat storage 70Y may be formed by one metal plate 71 or may be formed by three or more metal plates 71. Since details of the metal plate 71 are similar to above-described details of the metal plates 71 of the heat storage 70X, repeated description will be omitted.

Each metal plate 71 is disposed in parallel with the second part 32 of the connection component 30. Each metal plate 71 includes an attachment hole 71h. The attachment hole 71h faces the attachment hole 32h of the second part 32 of the connection component 30 when seen from the Z direction.

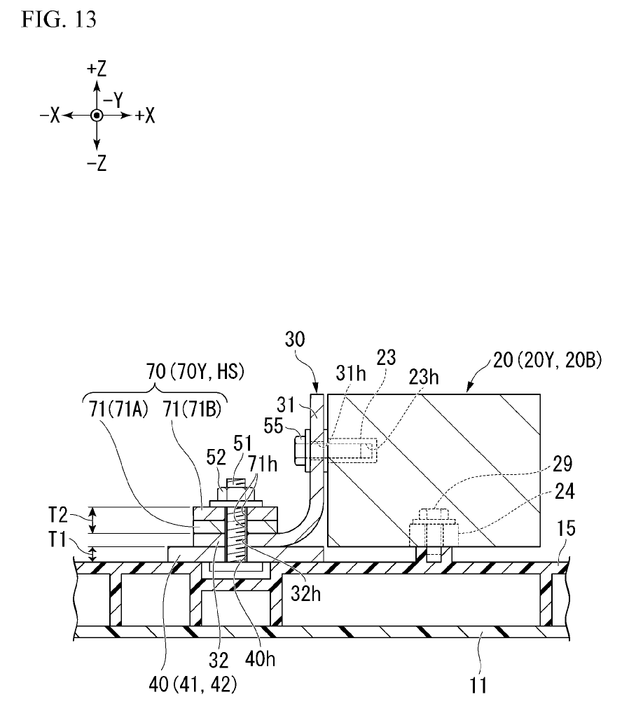

In the present embodiment, the fastening member 51 inserted into the attachment hole 40h of the bus bar 40 and the attachment hole 32h of the second part 32 of the connection component 30 is inserted into the attachment holes 71h of the plurality of (for example, two) metal plates 71 (see FIG. 13). Then, the engagement member 52 is engaged with the tip end portion of the fastening member 51 inserted into the attachment hole 40h of the bus bar 40, the attachment hole 32h of the second part 32 of the connection component 30, and the attachment holes 71h of the plurality of (for example, two) metal plates 71 (see FIG. 13). With this configuration, the second part 32 of the connection component 30, the bus bar 40, and the plurality of (for example, two) metal plates 71 are fixed by the fastening member 51. In the present embodiment, the second part 32 of the connection component 30, the bus bar 40, and the plurality of (for example, two) metal plates 71 are fastened together using the fastening member 51.

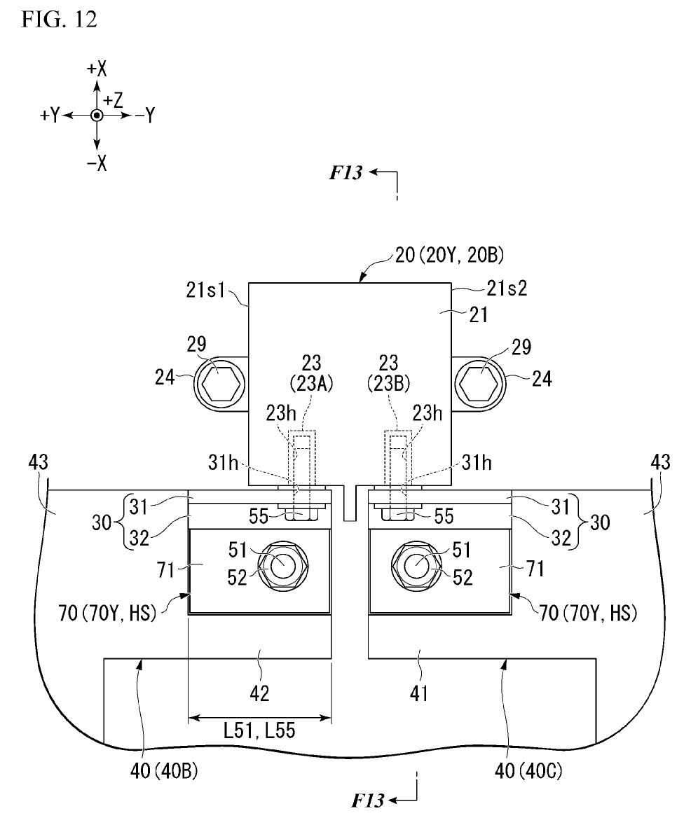

FIG. 12 is a plan view for explaining the heat storage 70Y. In the present embodiment, the plurality of metal plates 71 have the same size and the same shape when seen from the Z direction. A length L55 of each metal plate 71 in the Y direction is equal to or greater than half of a length L51 of the second part 32 of the connection component 30 in the Y direction, for example.

In the present embodiment, the case 21 of the electronic component 20Y includes a first side surface 21s1, which is an end surface on the +Y direction side, and a second side surface 21s2, which is an end surface on the -Y direction side. Also, the connection component 30 and the metal plate 71 corresponding to the terminal 23A located on the +Y direction side out of the two terminals 23 extend on the +Y direction side beyond the first side surface 21s1 of the case 21 of the electronic component 20Y. On the other hand, the connection component 30 and the metal plate 71 corresponding to the terminal 23B located on the -Y direction side out of the two terminals 23 extend on the -Y direction side beyond the second side surface 21s2 of the case 21 of the electronic component 20Y.

FIG. 13 is a sectional view of the structure illustrated in FIG. 12 along the line F13-F13. In the present embodiment, the plurality of (for example, two) metal plates 71 are disposed on the side opposite to the first connection portion 41 or the second connection portion 42 of the bus bar 40 with respect to the second part 32 of the connection component 30. For example, the first connection portion 41 or the second connection portion 42 of the bus bar 40 is disposed below the second part 32 of the connection component 30. The first connection portion 41 or the second connection portion 42 of the bus bar 40 is disposed between the second part 32 of the connection component 30 and the base member 15 in the Z direction. The first connection portion 41 or the second connection portion 42 of the bus bar 40 is in contact with the second part 32 of the connection component 30 from the lower side. On the other hand, the plurality of (for example, two) metal plates 71 are disposed above the second part 32 of the connection component 30 and is exposed to the internal space of the housing 10. One metal plate 71 from among the plurality of metal plates 71 is in contact with the second part 32 of the connection component 30 from the upper side.

In the present embodiment, a total thickness T2 (that is, the thickness of the heat storage HS in the Z direction), which is the sum of the thicknesses of the plurality of metal plates 71 in the Z direction, is thicker than a thickness T1 of the first connection portion 41 or the second connection portion 42 of the bus bar 40 in the Z direction.

### 7.4 Modifications of Heat Storage Corresponding to Electronic Component of Second Type

Some modifications of the heat storage 70Y will be described below. Note that configurations other than those described below in each modification are the same as the aforementioned configurations of the heat storage 70Y.

### 7.4.1 First Modification

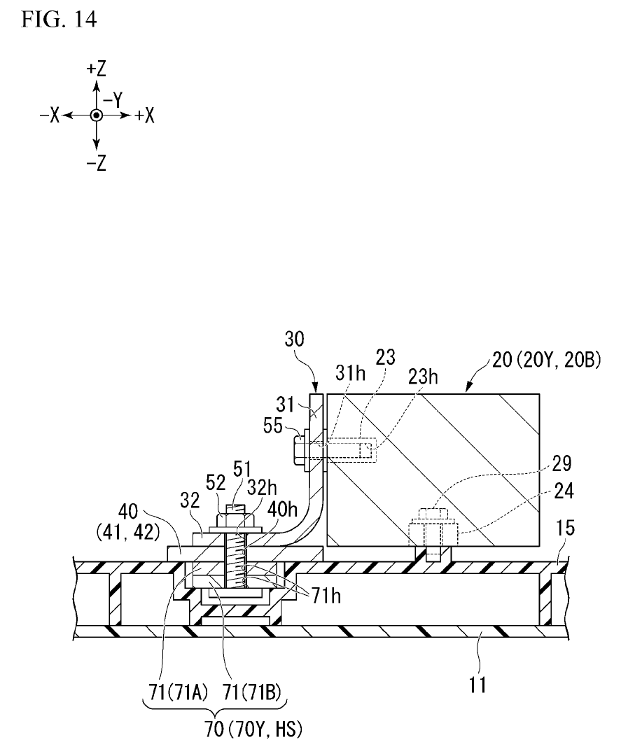

FIG. 14 is a sectional view for explaining the heat storage 70Y of a first modification. In the present modification, the plurality of (for example, two) metal plates 71 are disposed on the side opposite to the second part 32 of the connection component 30 with respect to the first connection portion 41 or the second connection portion 42 of the bus bar 40. For example, the first connection portion 41 or the second connection portion 42 of the bus bar 40 is disposed below the second part 32 of the connection component 30 and is in contact with the second part 32 of the connection component 30 from the lower side. The plurality of (for example, two) metal plates 71 are disposed below the first connection portion 41 or the second connection portion 42 of the bus bar 40. The plurality of (for example, two) metal plates 71 are disposed between the first connection portion 41 or the second connection portion 42 of the bus bar 40 and the base member 15 in the Z direction. One metal plate 71 from among the plurality of metal plates 71 is in contact with the first connection portion 41 or the second connection portion 42 of the bus bar 40 from the lower side.

### 7.4.2 Second Modification

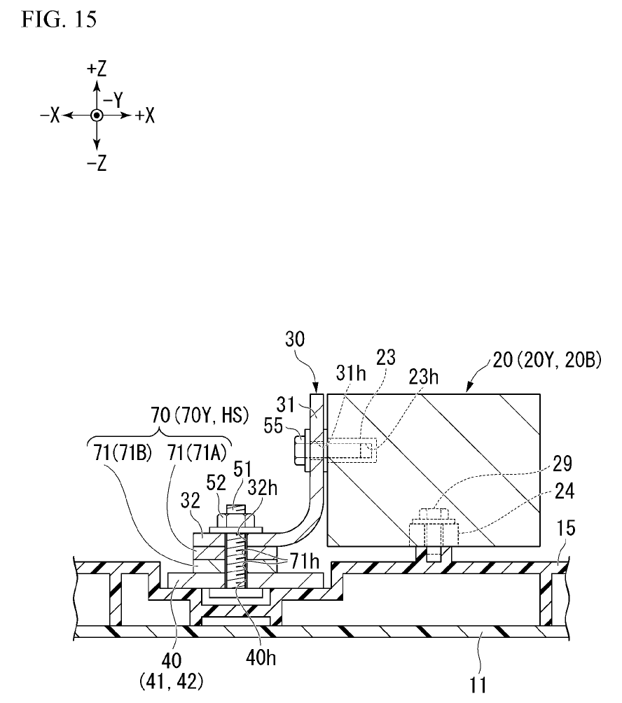

FIG. 15 is a sectional view for explaining the heat storage 70Y of a second modification. In the present modification, the plurality of (for example, two) metal plates 71 are disposed between the second part 32 of the connection component 30 and the first connection portion 41 or the second connection portion 42 of the bus bar 40 in the Z direction. The plurality of (for example, two) metal plates 71 are sandwiched between the second part 32 of the connection component 30 and the first connection portion 41 or the second connection portion 42 of the bus bar 40 in the Z direction. For example, one metal plate 71 (first metal plate 71A) from among the plurality of metal plates 71 is in contact with the second part 32 of the connection component 30 from the lower side. One different metal plate 71 (second metal plate 71B) from among the plurality of metal plates 71 is in contact with the first connection portion 41 or the second connection portion 42 of the bus bar 40 from the upper side.

### 7.4.3 Third Modification

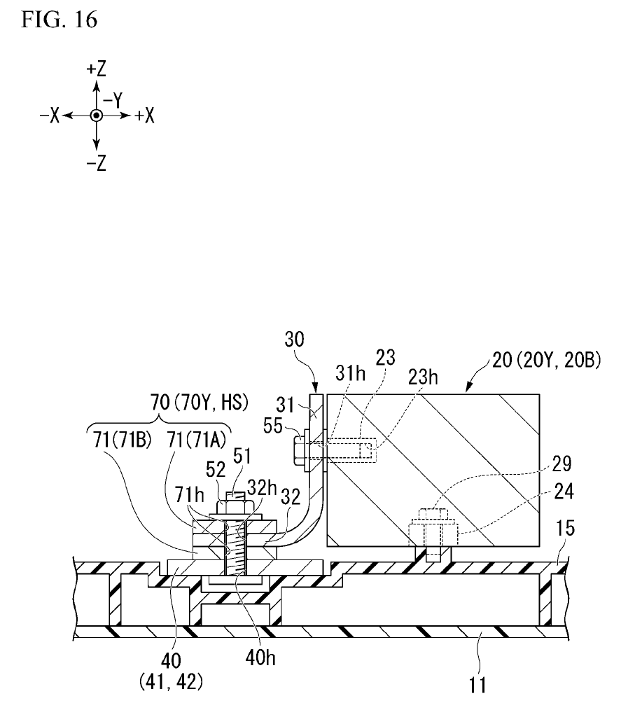

FIG. 16 is a sectional view for explaining the heat storage 70Y of a third modification. In the present modification, the plurality of (for example, two) metal plates 71 are disposed in a divided manner on both sides of the second part 32 of the connection component 30 in the Z direction. For example, one metal plate 71 (first metal plate 71A) from among the plurality of metal plates 71 is disposed above the second part 32 of the connection component 30 and is in contact with the second part 32 of the connection component 30 from the upper side. One different metal plate 71 (second metal plate 71B) from among the plurality of metal plates 71 is disposed between the second part 32 of the connection component 30 and the first connection portion 41 or the second connection portion 42 of the bus bar 40. For example, the second metal plate 71B is sandwiched between the second part 32 of the connection component 30 and the first connection portion 41 or the second connection portion 42 of the bus bar 40 in the Z direction. The second metal plate 71B is in contact with the second part 32 of the connection component 30 from the lower side and is in contact with the first connection portion 41 or the second connection portion 42 of the bus bar 40 from the upper side.

### 7.4.4 Fourth Modification

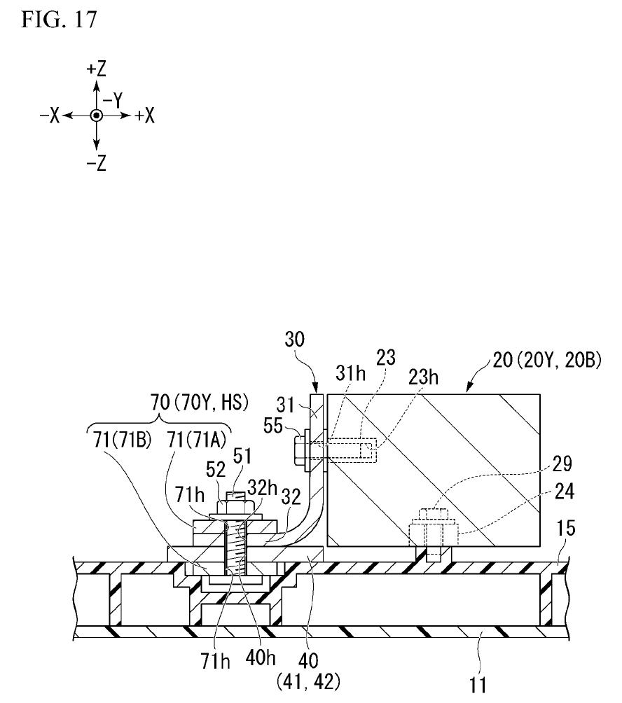

FIG. 17 is a sectional view for explaining the heat storage 70Y of a fourth modification. In the present modification, the plurality of (for example, two) metal plates 71 are disposed in a divided manner on both sides of the second part 32 of the connection component 30 and the connection portion (the first connection portion 41 or the second connection portion 42) of the bus bar 40 in the Z direction. For example, one metal plate 71 (first metal plate 71A) from among the plurality of metal plates 71 is disposed above the second part 32 of the connection component 30 and is in contact with the second part 32 of the connection component 30 from the upper side. In the present modification, the first connection portion 41 or the second connection portion 42 of the bus bar 40 is disposed below the second part 32 of the connection component 30 and is in contact with the second part 32 of the connection component 30 from the lower side. One different metal plate 71 (second metal plate 71B) from among the plurality of metal plates 71 is disposed below the first connection portion 41 or the second connection portion 42 of the bus bar 40 and is in contact with the first connection portion 41 or the second connection portion 42 of the bus bar 40 from the lower side. In other words, the first metal plate 71A is disposed on the first side (+Z direction side) in the Z direction with respect to the second part 32 of the connection component 30 and the connection portion (the first connection portion 41 or the second connection portion 42) of the bus bar 40. On the other hand, the second metal plate 71B is disposed on the second side (-Z direction side), which is the side opposite to the first side in the Z direction with respect to the second part 32 of the connection component 30 and the connection portion (the first connection portion 41 or the second connection portion 42) of the bus bar 40.

### 7.5 Advantages of Heat Storage of First Aspect

As a comparative example, an electrical connection unit with no heat storage 70 will be considered. In such a configuration, a significant temperature rise may occur in a part of the electrical connection unit in a case where a large current flows in a short period of time, for example.

Thus, in the present embodiment, the electrical connection unit includes: the connection target component including the metal plate portion (for example, the electronic component 20 including the terminal 23 or the connection component 30 including the second part 32); the routing member (for example, the bus bar 40) that includes the connection portion (for example, the first connection portion 41 or the second connection portion 42) that overlaps the metal plate portion when seen from a first direction, which is the plate thickness direction of the metal plate portion, the routing member being electrically connected to the metal plate portion; and the one or more metal plates (for example, the metal plates 71) that overlap the metal plate portion when seen from the first direction. According to such a configuration, a part of heat generated in the electrical connection unit can be stored by the one or more metal plates. Alternatively, the heat dissipation area can be increased by the one or more metal plates. With this action, it is possible to improve the thermal characteristics (for example, a heat storage property and/or a heat dissipation property) of the electrical connection unit.

Here, a case in which a rectangular parallelepiped metal block is used as a heat storage member is also conceivable. However, since such a metal block is not inexpensive, use of the metal block as the heat storage member is disadvantageous for cost reduction of the electrical connection unit. On the other hand, the metal plate having the above configuration can be obtained at lower cost than the metal block. Therefore, according to the above configuration, it is possible to easily achieve cost reduction of the electrical connection unit while improving the thermal characteristics of the electrical connection unit.

In the present embodiment, the metal plate portion includes the first attachment hole (for example, the attachment hole 23h or the attachment hole 32h) penetrating through the metal plate portion in the first direction. The connection portion of the routing member includes the second attachment hole (for example, the attachment hole 40h) facing the first attachment hole. Each of the one or more metal plates includes the third attachment hole (for example, the attachment hole 71h) facing the first attachment hole. The connection target component, the routing member, and the one or more metal plates are fixed by the fastening member (for example, the fastening member 51) inserted into the first attachment hole, the second attachment hole, and the third attachment hole. According to such a configuration, the connection target component, the routing member, and the one or more metal plates can be fixed with a simple fastening structure. With this structure, it is possible to facilitate miniaturization and/or cost reduction of the electrical connection unit.

In the present embodiment, the connection target component is an electronic component. The metal plate portion is a terminal of the electronic component. According to such a configuration, it is possible to easily cause heat to move directly from the terminal of the electronic component to the one or more metal plates. With this action, it is possible to further improve the thermal characteristics (for example, a heat storage property and/or a heat dissipation property) of the electrical connection unit.

In the present embodiment, the connection target component is a connection component disposed between the electronic component and the routing member. According to such a configuration, it is possible to easily cause heat to move from the electronic component to the one or more metal plates even in a case where it is difficult to attach the metal plates directly to the terminal of the electronic component. With this action, it is possible to further improve the thermal characteristics (for example, a heat storage property and/or a heat dissipation property) of the electrical connection unit.

In the present embodiment, each of the one or more metal plates is larger than the metal plate portion when seen from the first direction. According to such a configuration, it is easy to increase the heat capacity of the heat storage formed by the one or more metal plates. With this configuration, it is possible to further improve thermal characteristics (for example, a heat storage property and/or a heat dissipation property) of the electrical connection unit.

In the present embodiment, the one or more metal plates include the first metal plate (for example, the first metal plate 71A) and the second metal plate (for example, the second metal plate 71B). According to such a configuration, it is possible to promote heat storage or heat dissipation of a part of the heat generated in the electrical connection unit by the plurality of metal plates. With this configuration, it is possible to further improve thermal characteristics (for example, a heat storage property and/or a heat dissipation property) of the electrical connection unit.

In the present embodiment, the first metal plate and the second metal plate are disposed on the side opposite to the connection portion of the routing member with respect to the metal plate portion. According to such a configuration, it is possible to reduce an energization resistance between the metal plate portion and the connection portion of the routing member as compared with a case where the metal plates are disposed between the metal plate portion and the connection portion of the routing member. With this configuration, it is possible to improve electrical characteristics of the electrical connection unit. In a case where the one metal plate is in contact with the metal plate portion, heat is more likely to move from the metal plate portion to the metal plate. With this configuration, it is possible to further improve thermal characteristics (for example, a heat storage property and/or a heat dissipation property) of the electrical connection unit. Also, according to the above configuration, it is possible to increase the heat dissipation area in a case where a gap is formed between the metal plates and the routing member by the metal plate portion being present between the metal plates and the routing member.

In the present embodiment, the first metal plate and the second metal plate are disposed on the side opposite to the metal plate portion with respect to the connection portion of the routing member. According to such a configuration, it is possible to reduce an energization resistance between the metal plate portion and the connection portion of the routing member as compared with a case where the metal plates are disposed between the metal plate portion and the connection portion of the routing member. With this configuration, it is possible to improve electrical characteristics of the electrical connection unit.

In the present embodiment, the first metal plate and the second metal plate are disposed in a divided manner on both sides in the first direction with respect to the metal plate portion. According to such a configuration, it is possible to dispose the two metal plates in a dispersed manner as compared with a case where the two metal plates are disposed together on one side with respect to the metal plate portion. With this configuration, it is possible to enhance the heat dissipation property of the two metal plates as compared with the case where the two metal plates are disposed together. Also, according to the above configuration, it is possible to easily reduce the distance between each of the two metal plates and the metal plate portion as compared with the case where two metal plates are disposed together on one side with respect to the metal plate portion. In other words, according to this configuration, heat is more likely to be transmitted from the metal plate portion to the two metal plates. With these actions, it is possible to further improve the thermal characteristics (for example, a heat storage property and/or a heat dissipation property) of the electrical connection unit.

In the present embodiment, the first metal plate and the second metal plate are disposed in a divided manner on both sides in the first direction with respect to the metal plate portion and the connection portion of the routing member. According to such a configuration, it is possible to dispose the two metal plates in a dispersed manner as compared with the case where the two metal plates are disposed together on one side with respect to the metal plate portion. With this configuration, it is possible to enhance the heat dissipation property of the two metal plates as compared with the case where the two metal plates are disposed together. According to the above configuration, it is possible to reduce an energization resistance between the metal plate portion and the connection portion of the routing member as compared with the case where the metal plates are disposed between the metal plate portion and the connection portion of the routing member. With this configuration, it is possible to improve electrical characteristics of the electrical connection unit.

### 8. Heat Storage of Second Aspect

### 8.1 Configuration of Heat Storage of Second Aspect

Next, a heat storage 80 of a second aspect will be described.

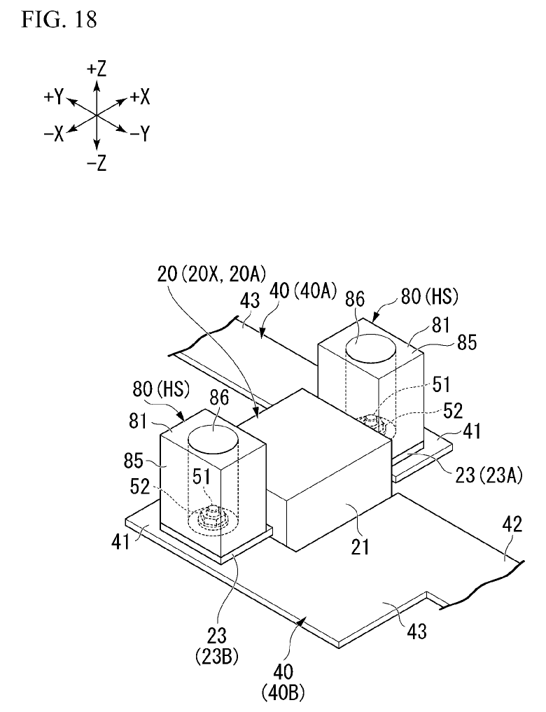

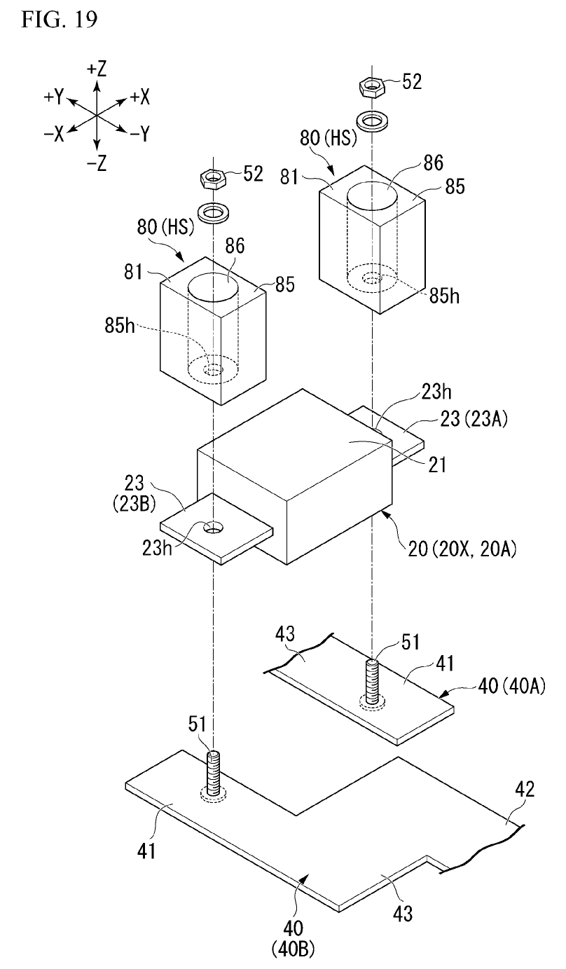

FIG. 18 is a perspective view illustrating a part of the electrical connection unit 1 including the heat storage 80 of the second aspect. FIG. 19 is a perspective view for explaining the heat storage 80 of the second aspect. The heat storage 80 of the second aspect is formed by, for example, one metal member 81. The metal member 81 is a rectangular parallelepiped metal block.

The metal member 81 is provided for the terminal 23 of the electronic component 20A, for example. The metal member 81 is formed of a material such as copper, a copper alloy, aluminum, or an aluminum alloy, for example. The metal member 81 is disposed in parallel with the terminal 23 of the electronic component 20A. The metal member 81 overlaps the terminal 23 of the electronic component 20A when seen from the Z direction. In the present embodiment, the metal member 81 is disposed on the side opposite to the first connection portion 41 of the bus bar 40 with respect to the terminal 23 of the electronic component 20A. The metal member 81 includes, for example, a block body 85 and a hole 86.

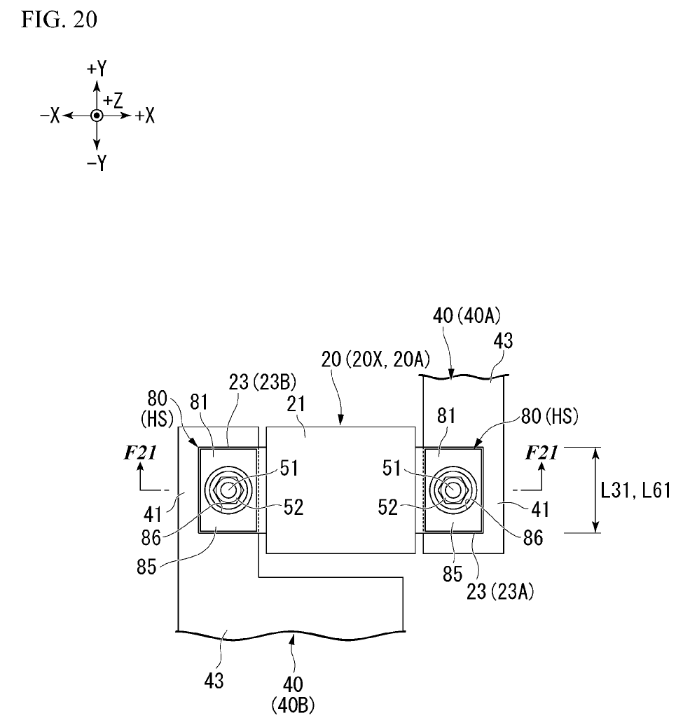

FIG. 20 is a plan view for explaining the heat storage 80 of the second aspect. The block body 85 is a metal portion with a rectangular parallelepiped outer shape. A length L61 of the block body 85 in the Y direction is equal to or greater than the length L31 of the terminal 23 of the electronic component 20A in the Y direction, for example. Note that the length L61 of the block body 85 in the Y direction may be shorter than the length L31 of the terminal 23 of the electronic component 20A in the Y direction.

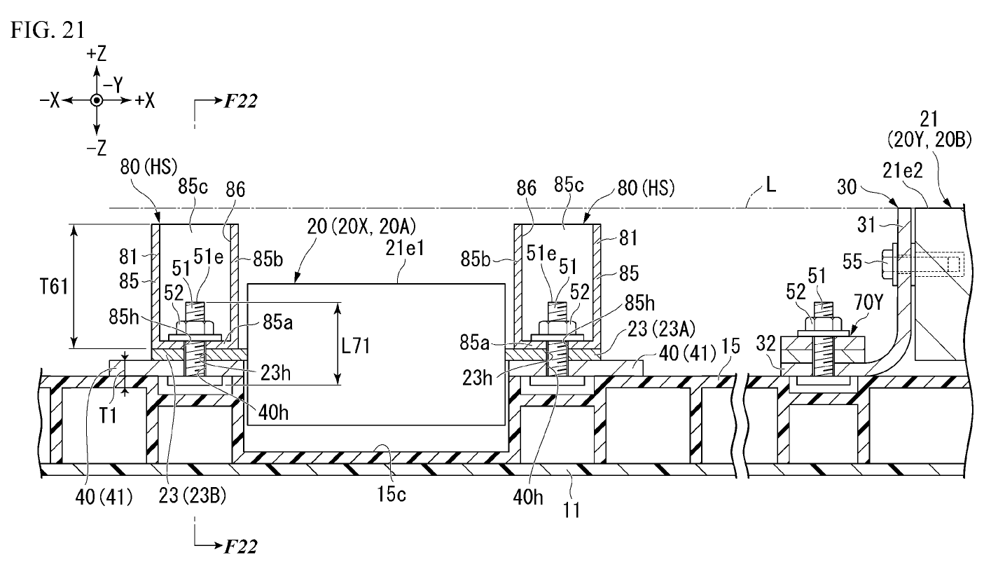

FIG. 21 is a sectional view of the structure illustrated in FIG. 20 along the line F21-F21. A thickness T61 of the block body 85 in the Z direction (that is, the thickness of the metal member 81 in the Z direction) is equal to or greater than double the thickness T1 of the first connection portion 41 of the bus bar 40 in the Z direction, for example. The thickness T61 of the block body 85 in the Z direction (that is, the thickness of the metal member 81 in the Z direction) is thicker than a length L71 of the fastening member 51 in the Z direction, for example.

In the present embodiment, the fastening member 51 includes an upper end 51e as an end on the +Z direction side. The block body 85 extends on the +Z direction side beyond the upper end 51e of the fastening member 51. In the present embodiment, the electronic component 20A includes an upper end 21e1 as an end on the +Z direction side. The upper end 21e1 is an example of a “first end”. The block body 85 extends in the +Z direction beyond the upper end 21e1 of the electronic component 20A, which is the electronic component 20X of the first type.

On the other hand, the electronic component 20B, which is the electronic component 20Y of the second type, includes an upper end 21e2 as an end on the +Z direction side. The upper end 21e2 of the electronic component 20B is located at the +Z direction side with respect to the upper end 21e1 of the electronic component 20A. The block body 85 does not exceed a virtual line L obtained by extending the upper end 21e1 of the electronic component 20B in the horizontal direction, for example. The block body 85 is disposed in a space between the terminal 23 of the electronic component 20A and the virtual line L. According to this configuration, it is possible to easily reduce the height of the electrical connection unit 1. In the example illustrated in FIG. 21, the base member 15 includes an accommodating portion 15c recessed toward the -Z direction. The electronic component 20A is disposed at the -Z direction side with respect to the electronic component 20B by a part of the electronic component 20A being disposed in the accommodating portion 15c of the base member 15.

The hole 86 is provided in the block body 85. The hole 86 is a cylindrical hole extending in the Z direction. The hole 86 is opened in the +Z direction. The diameter of the hole 86 is larger than the engagement member 52, which is engaged with the fastening member 51, and a washer. The block body 85 includes a base portion 85a, a peripheral wall portion 85b, a space portion 85c, and an attachment hole 85h by the hole 86 being provided.

The base portion 85a is a plate portion along the horizontal direction. The base portion 85a faces the terminal 23 of the electronic component 20 when seen from the Z direction. For example, the base portion 85a is in contact with the terminal 23 of the electronic component 20 from the +Z direction side. The peripheral wall portion 85b extends in the Z direction from the peripheral edge portion of the base portion 85a toward the side opposite to the terminal 23 of the electronic component 20A. The peripheral wall portion 85b surrounds the periphery of the hole 86. The space portion 85c is a space formed by the hole 86 inside the peripheral wall portion 85b. The space portion 85c faces the base portion 85a when seen from the Z direction. The space portion 85c is opened on the +Z direction side.

The attachment hole 85h is provided in the base portion 85a. The attachment hole 85h is a through-hole penetrating through the base portion 85a in the Z direction. The attachment hole 85h faces the space portion 85c when seen from the Z direction. The attachment hole 85h faces the attachment hole 23h of the terminal 23 of the electronic component 20A when seen from the Z direction. An inner circumferential surface of the attachment hole 85h does not have, for example, a screw groove. However, the attachment hole 85h may be a hole having a screw groove to allow the fastening member 51 to be engaged therewith. Also, the attachment hole 85h may be a bottomed hole opened toward the -Z direction. The attachment hole 85h is an example of a “third attachment hole”.

In the present embodiment, the fastening member 51 inserted into the attachment hole 40h of the bus bar 40 and the attachment hole 23h of the terminal 23 of the electronic component 20A is inserted into the attachment hole 85h of the block body 85. Then, the engagement member 52 is engaged with the tip end portion of the fastening member 51 inserted into the attachment hole 40h of the bus bar 40, the attachment hole 23h of the terminal 23 of the electronic component 20A, and the attachment hole 85h of the block body 85. The engagement member 52 is accommodated in the space portion 85c of the block body 85. With this configuration, the terminal 23 of the electronic component 20A, the bus bar 40, and the metal member 81 are fixed by the fastening member 51. In the present embodiment, the terminal 23 of the electronic component 20A, the bus bar 40, and the metal member 81 are fastened together by using the fastening member 51.

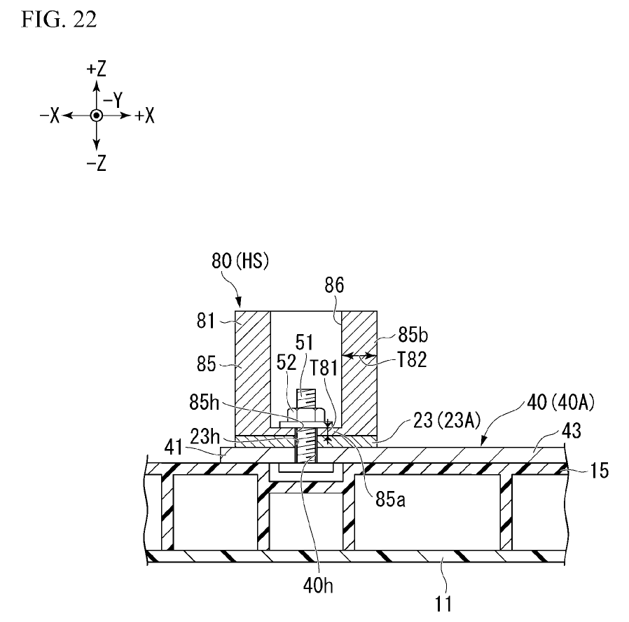

FIG. 22 is a sectional view of the structure illustrated in FIG. 21 along the line F22-F22. In the present embodiment, a thickness T82 of at least a part of the peripheral wall portion 85b of the block body 85 in the X direction is thicker than a thickness T81 of the base portion 85a of the block body 85 in the Z direction. According to this configuration, it is possible to easily secure a larger heat capacity of the metal member 81.

### 8.2 Modifications of Heat Storage of Second Aspect

Next, some modifications of the heat storage 80 will be described. Note that configurations other than those described below in each modification are the same as the aforementioned configurations of the heat storage 80.

### 8.2.1 First Modification

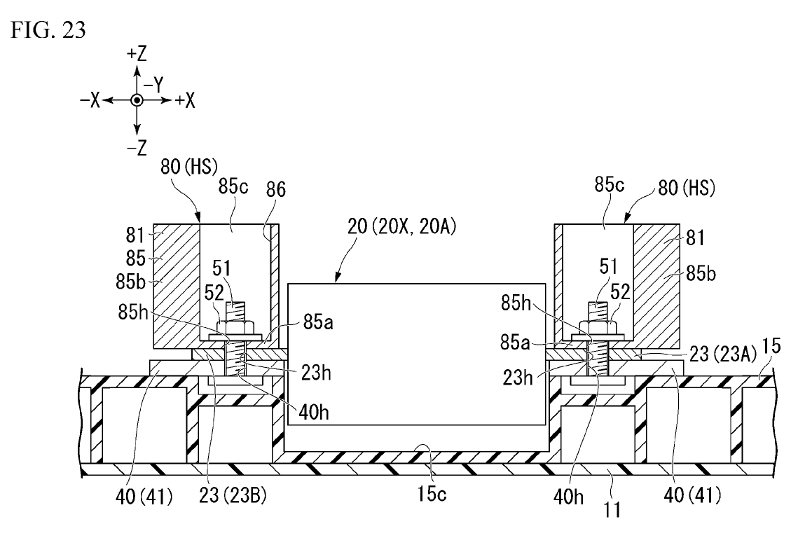

FIG. 23 is a sectional view for explaining the heat storage 80 of a first modification. In the present modification, the metal member 81 is larger than the terminal 23 of the electronic component 20A when seen from the Z direction. For example, the length of the metal member 81 in the X direction is longer than the length of the terminal 23 of the electronic component 20A in the X direction. Instead of or in addition to this, the length of the metal member 81 in the Y direction may be longer than the length of the terminal 23 of the electronic component 20A in the Y direction. According to such a configuration, it is possible to increase the heat capacity and the heat dissipation area of the heat storage 80 as compared with the aforementioned embodiment. With this configuration, it is possible to further improve thermal characteristics (for example, a heat storage property and/or a heat dissipation property) of the electrical connection unit 1.

### 8.2.2 Second Modification

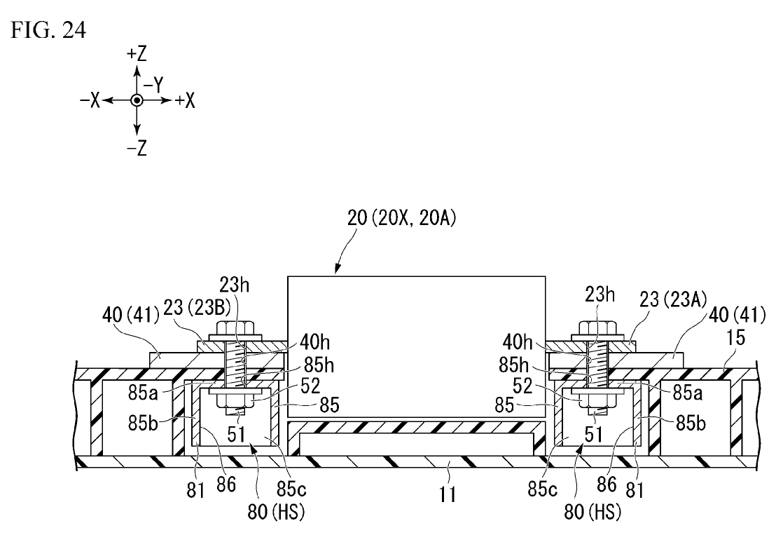

FIG. 24 is a sectional view for explaining the heat storage 80 of a second modification. In the present modification, the metal member 81 is disposed on the side opposite to the terminal 23 of the electronic component 20A with respect to the first connection portion 41 of the bus bar 40. For example, the first connection portion 41 of the bus bar 40 is disposed below the terminal 23 of the electronic component 20A and is in contact with the terminal 23 of the electronic component 20A from the lower side. The metal member 81 is disposed below the first connection portion 41 of the bus bar 40. The metal member 81 is disposed between the first connection portion 41 of the bus bar 40 and the base member 15 in the Z direction. The metal member 81 is in contact with the first connection portion 41 of the bus bar 40 from the lower side.

### 8.2.3 Third Modification

In the aforementioned embodiment, the heat storage 80 is provided for the terminal 23 of the electronic component 20A. Note that the heat storage 80 may be provided for the connection component 30 instead of the terminal 23 of the electronic component 20A. In other words, the heat storage 80 of the second aspect may be provided for the second part 32 of the connection component 30 instead of the heat storage 70Y of the first aspect.

### 8.3 Advantages of Heat Storage of Second Aspect

As a comparative example, an electrical connection unit with no heat storage 80 will be considered. In such a configuration, a significant temperature rise may occur in a part of the electrical connection unit in a case where a large current flows in a short period of time, for example.

Thus, in the present embodiment, the electrical connection unit includes: the connection target component including the metal plate portion (for example, the electronic component 20 including the terminal 23 or the connection component 30 including the second part 32); the routing member (for example, the bus bar 40) that includes the connection portion (for example, the first connection portion 41 or the second connection portion 42) that overlaps the metal plate portion when seen from a first direction, which is the plate thickness direction of the metal plate portion, the routing member being electrically connected to the metal plate portion; and the metal member (for example, the metal member 81) that overlaps the metal plate portion when seen from the first direction. The metal member is a metal block in which the thickness of the metal member in the first direction is equal to or greater than double the thickness of the connection portion of the routing member in the first direction. According to such a configuration, it is possible to store a part of heat generated by the electrical connection unit with the metal member which is the metal block. Alternatively, it is possible to increase the heat dissipation area by the metal member which is the metal block. With this action, it is possible to improve the thermal characteristics (for example, a heat storage property and/or a heat dissipation property) of the electrical connection unit.

In the present embodiment, the metal plate portion includes the first attachment hole (for example, the attachment hole 23h or the attachment hole 32h) penetrating through the metal plate portion in the first direction. The connection portion of the routing member includes the second attachment hole (for example, the attachment hole 40h) facing the first attachment hole. The metal member includes the third attachment hole (for example, the attachment hole 85h) facing the first attachment hole. The connection target component, the routing member, and the metal member are fixed by the fastening member (for example, the fastening member 51) inserted into the first attachment hole, the second attachment hole, and the third attachment hole. According to such a configuration, the connection target component, the routing member, and the metal member can be fixed by a simple fastening structure. With this structure, it is possible to facilitate miniaturization and/or cost reduction of the electrical connection unit.

In the present embodiment, the metal member includes the base portion (for example, the base portion 85a) that faces the metal plate portion, the peripheral wall portion (for example, the peripheral wall portion 85b) that extends in the first direction from the peripheral edge portion of the base portion toward the side opposite to the metal plate portion, and the space portion (for example, the space portion 85c) that is formed inside the peripheral wall portion. The third attachment hole is provided in the base portion and faces the space portion. According to such a configuration, it is possible to reduce the size of the fastening member 51 for fixing the metal block. This facilitates cost reduction of the electrical connection unit.

In the present embodiment, the connection target component is an electronic component. The metal plate portion is a terminal of the electronic component. According to such a configuration, it is possible to easily cause heat to move directly from the terminal of the electronic component to the metal member, which is the metal block. With this action, it is possible to further improve the thermal characteristics (for example, a heat storage property and/or a heat dissipation property) of the electrical connection unit.

In the present embodiment, the metal member is disposed on the side opposite to the connection portion of the routing member with respect to the metal plate portion. According to such a configuration, it is possible to reduce an energization resistance between the metal plate portion and the connection portion of the routing member as compared with the case where the metal member is disposed between the metal plate portion and the connection portion of the routing member. With this configuration, it is possible to improve electrical characteristics of the electrical connection unit. Also, in a case where the metal member is in contact with the metal plate portion, heat is more likely to move from the metal plate portion to the metal member. With this configuration, it is possible to further improve thermal characteristics (for example, a heat storage property and/or a heat dissipation property) of the electrical connection unit.

In the present embodiment, the connection target component includes the first end (for example, the upper end 21e1) in the first direction. The metal member extends in the first direction beyond the first end of the connection target component. According to such a configuration, it is possible to easily increase the heat capacity of the heat storage formed by the metal member. With this configuration, it is possible to further improve thermal characteristics (for example, a heat storage property and/or a heat dissipation property) of the electrical connection unit.

### 9. Heat Storage of Third Aspect

### 9.1 Configuration of Heat Storage of Third Aspect

Next, a heat storage 80' of a third aspect will be described.

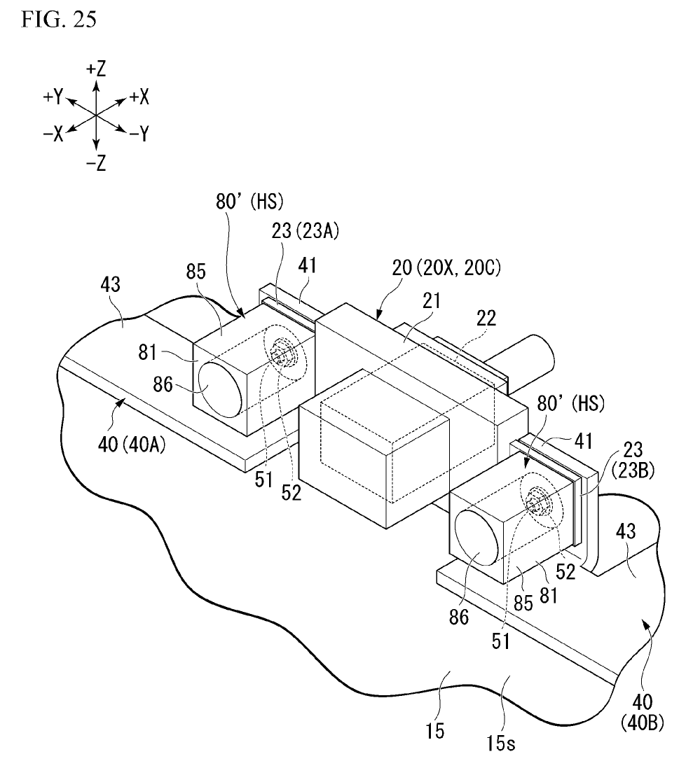

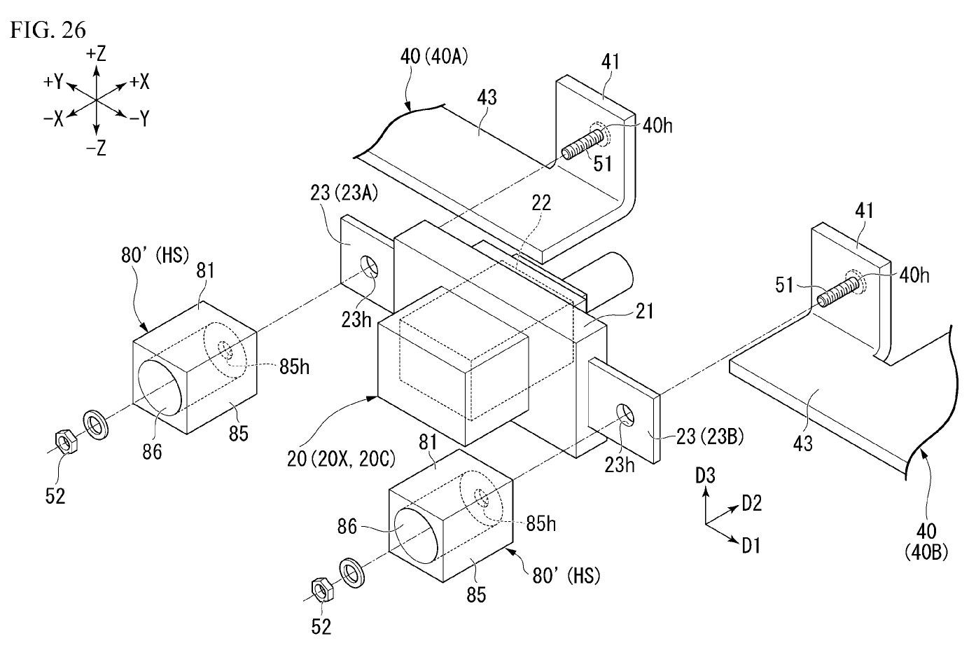

FIG. 25 is a perspective view illustrating a part of the electrical connection unit 1 including the heat storage 80' of the third aspect. FIG. 26 is a perspective view for explaining the heat storage 80' of the third aspect.

In the present embodiment, the base member 15 includes a support surface 15s. The support surface 15s is a surface facing the +Z direction side. The support surface 15s extends in the X direction and the Y direction. The support surface 15s is disposed below the extending portion 43 of the bus bar 40 and supports the extending portion 43 of the bus bar 40 from the lower side. The support surface 15s is an example of a “first support surface”.

### Bus Bar

First, the bus bar 40 will be described. In the present embodiment, the extending portion 43 of the bus bar 40 is a plate portion along the X direction and the Y direction. The extending portion 43 of the bus bar 40 is disposed in parallel with the support surface 15s of the base member 15 and extends along the support surface 15s of the base member 15.

On the other hand, the first connection portion 41 of the bus bar 40 is disposed in an upright posture with respect to the support surface 15s of the base member 15. For example, the first connection portion 41 of the bus bar 40 is a plate portion along the Y direction and the Z direction. The first connection portion 41 of the bus bar 40 is formed by a part of the bus bar 40, which is the plate member, being bent from the extending portion 43. The attachment hole 40h of the bus bar 40 penetrates through the first connection portion 41 of the bus bar 40 in the horizontal direction (for example, the X direction). The fastening member 51 fixed to the first connection portion 41 of the bus bar 40 projects in the horizontal direction (for example, the -X direction) from the first connection portion 41 of the bus bar 40.

### Electronic Component

Next, each electronic component 20 will be described. In the present embodiment, the electrical connection unit 1 includes an electronic component 20C as an example of the electronic component 20. The electronic component 20C is, for example, the aforementioned electronic component 20X of the first type. The electronic component 20C includes, for example, a case 21, a component main body 22, and a plurality of terminals 23. The electronic component 20C is an electronic component with a large dimension in a specific direction (a direction D2, which will be described later).

Here, the direction in which the plurality of terminals 23 of the electronic component 20C are aligned is defined as a direction D1, the plate thickness direction of the terminals 23 of the electronic component 20C is defined as the direction D2, and the direction intersecting (for example, orthogonal to) the direction D1 and the direction D2 is defined as a direction D3. Also, the electronic component 20C is disposed in a laterally facing posture with the direction D2 following the horizontal direction (for example, the X direction) in the present embodiment. For example, the electronic component 20C is disposed with the direction D1 following the Y direction, with the direction D2 following the X direction, and with the direction D3 following the Z direction. According to the arrangement in such a posture, it is possible to reduce the height of the electrical connection unit 1.

In other words, the electronic component 20C is disposed with the terminal 23 in an upright posture with respect to the support surface 15s of the base member 15. The terminal 23 is a plate portion along the Y direction and the Z direction. The attachment hole 23h is a through-hole penetrating through the terminal 23 in the X direction. The first connection portion 41 of the bus bar 40 overlaps the terminal 23 of the electronic component 20C when seen from the X direction. The attachment hole 40h of the first connection portion 41 of the bus bar 40 faces the attachment hole 23h of the terminal 23 of the electronic component 20C when seen from the X direction.

### Heat Storage

Next, a heat storage 80' of a third aspect will be described. The heat storage 80' of the third aspect is formed by, for example, one metal member 81 similarly to the heat storage 80 of the second aspect. The metal member 81 is a rectangular parallelepiped metal block. Since details of the metal member 81 are the same as details of the metal member 81 of the heat storage 80 of the second aspect, repeated description will be omitted.

The metal member 81 is disposed in parallel with the terminal 23 of the electronic component 20C. In the present embodiment, the metal member 81 overlaps the terminal 23 of the electronic component 20C when seen from the X direction. In the present embodiment, the metal member 81 is disposed on the side opposite to the first connection portion 41 of the bus bar 40 with respect to the terminal 23 of the electronic component 20C. The metal member 81 includes, for example, a block body 85 and a hole 86.

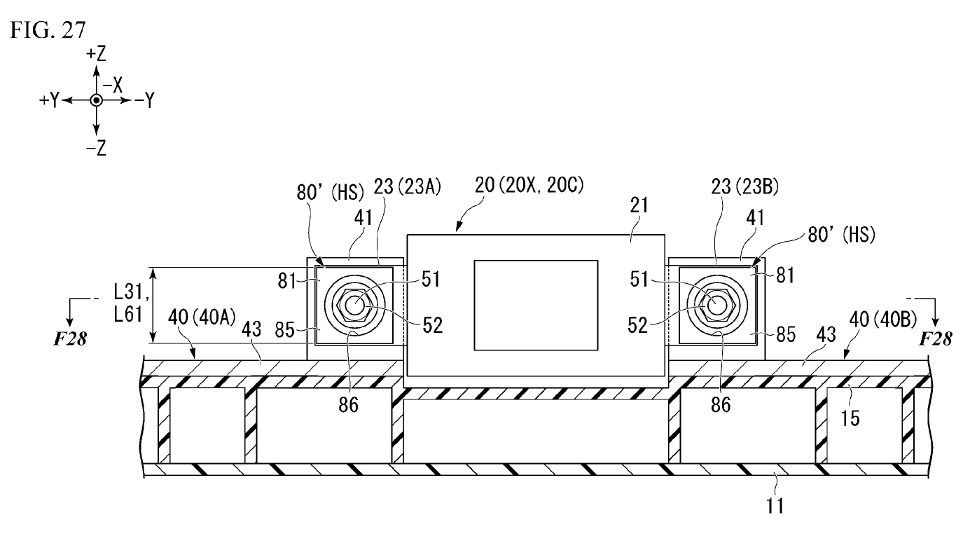

FIG. 27 is a sectional view for explaining the heat storage 80' of the third aspect. The block body 85 is a metal portion with a rectangular parallelepiped outer shape. A length L61 of the block body 85 in the Z direction is equal to or greater than the length L31 of the terminal 23 of the electronic component 20C in the Z direction, for example. Note that the length L61 of the block body 85 in the Z direction may be shorter than the length L31 of the terminal 23 of the electronic component 20C in the Z direction.

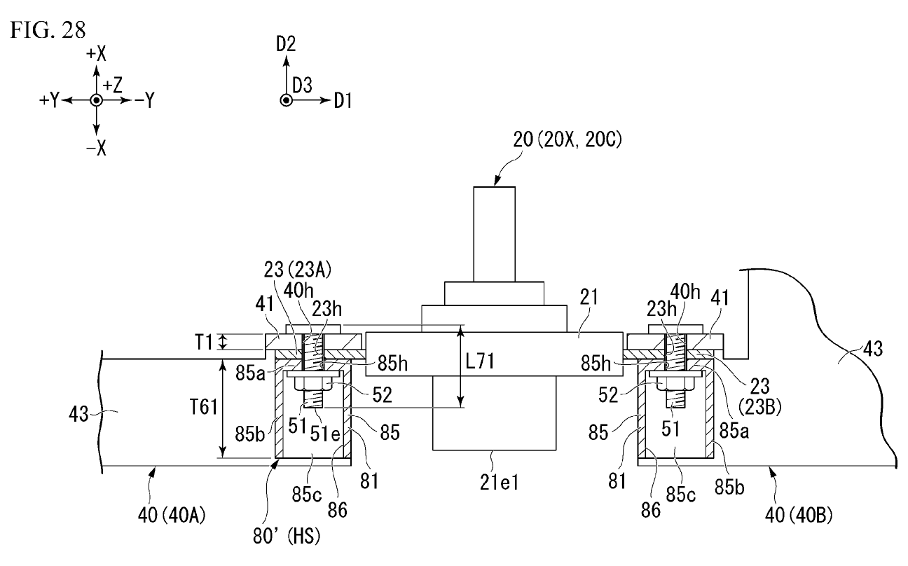

FIG. 28 is a sectional view of the structure illustrated in FIG. 27 along the line F28-F28. A thickness T61 of the block body 85 in the X direction (that is, the thickness of the metal member 81 in the X direction) is equal to or greater than double the thickness T1 of the first connection portion 41 of the bus bar 40 in the X direction, for example. The thickness T61 of the block body 85 in the X direction (that is, the thickness of the metal member 81 in the X direction) is thicker than the length L71 of the fastening member 51 in the X direction, for example.

In the present embodiment, the fastening member 51 includes an end 51e as an end on the -X direction side. The block body 85 extends on the -X direction side beyond the end 51e of the fastening member 51. In the present embodiment, the electronic component 20C includes the end 21e1 as an end on the -X direction side. The end 21e1 is an example of a “first end”. The block body 85 extends on the -X direction side beyond the end 21e1 of the electronic component 20C.

The hole 86 is provided in the block body 85. The hole 86 is a cylindrical hole extending in the X direction. The hole 86 is opened in the -X direction. The diameter of the hole 86 is larger than the engagement member 52, which is engaged with the fastening member 51, and a washer. The block body 85 includes a base portion 85a, a peripheral wall portion 85b, a space portion 85c, and an attachment hole 85h by the hole 86 being provided.

The base portion 85a is a plate portion along the Y direction and the Z direction. The base portion 85a faces the terminal 23 of the electronic component 20C when seen from the X direction. For example, the base portion 85a is in contact with the terminal 23 of the electronic component 20C from the -X direction side. The peripheral wall portion 85b extends in the X direction from the peripheral edge portion of the base portion 85a toward the side opposite to the terminal 23 of the electronic component 20C. The peripheral wall portion 85b surrounds the periphery of the hole 86. The space portion 85c is a space formed by the hole 86 inside the peripheral wall portion 85b. The space portion 85c faces the base portion 85a when seen from the X direction. The space portion 85c is opened on the -X direction side.

The attachment hole 85h is provided in the base portion 85a. The attachment hole 85h is a through-hole penetrating the base portion 85a in the X direction. The attachment hole 85h faces the attachment hole 23h of the terminal 23 of the electronic component 20C when seen from the X direction. The attachment hole 85h is an example of a “third attachment hole”.

In the present embodiment, the fastening member 51 inserted into the attachment hole 40h of the bus bar 40 and the attachment hole 23h of the terminal 23 of the electronic component 20C is inserted into the attachment hole 85h of the block body 85. Then, the engagement member 52 is engaged with the tip end portion of the fastening member 51 inserted into the attachment hole 40h of the bus bar 40, the attachment hole 23h of the terminal 23 of the electronic component 20A, and the attachment hole 85h of the block body 85. The engagement member 52 is accommodated in the space portion 85c of the block body 85. With this configuration, the terminal 23 of the electronic component 20C, the bus bar 40, and the metal member 81 are fixed by the fastening member 51. In the present embodiment, the terminal 23 of the electronic component 20C, the bus bar 40, and the metal member 81 are fastened together by using the fastening member 51.

### 9.2 Modifications of Heat Storage of Third Aspect

Next, several modifications of the heat storage 80' will be described. Note that configurations other than those described below in each modification are the same as the aforementioned configurations of the heat storage 80'.

### 9.2.1 First Modification

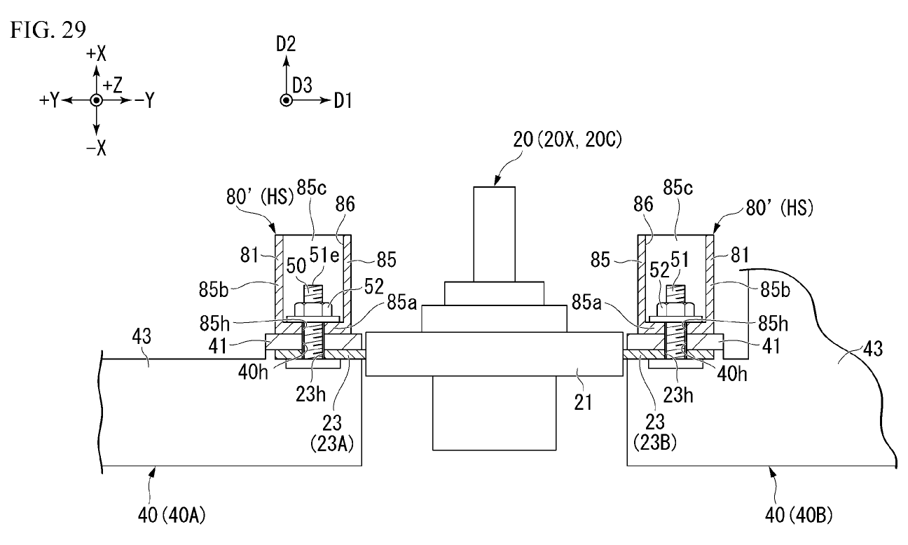

FIG. 29 is a sectional view for explaining the heat storage 80' of a first modification. In the present modification, the metal member 81 is disposed on the side opposite to the terminal 23 of the electronic component 20C with respect to the first connection portion 41 of the bus bar 40. For example, the first connection portion 41 of the bus bar 40 is disposed on the +X direction side with respect to the terminal 23 of the electronic component 20C and is in contact with the terminal 23 of the electronic component 20C on the +X direction side. The metal member 81 is disposed on the +X direction side with respect to the first connection portion 41 of the bus bar 40 and is in contact with the first connection portion 41 of the bus bar 40 on the +X direction side.

### 9.2.2 Second Modification

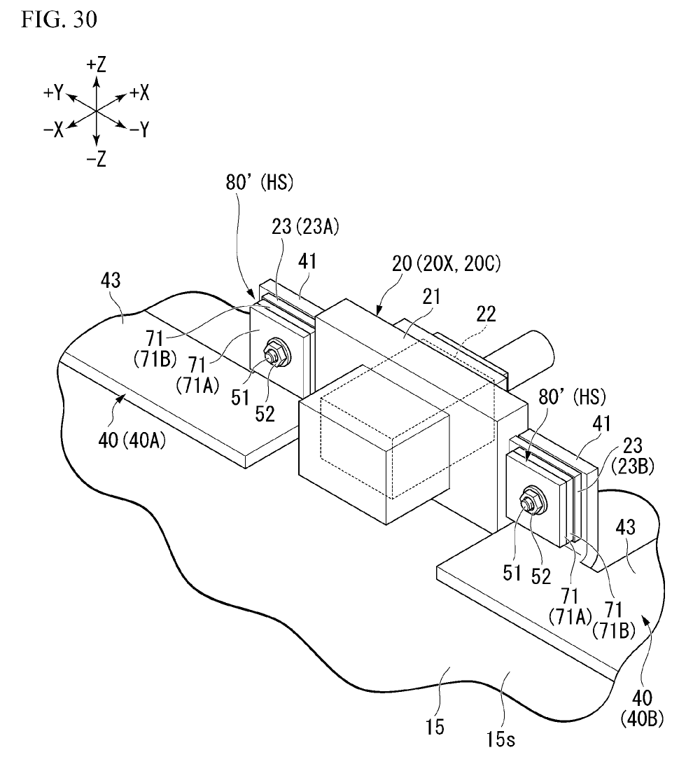

FIG. 30 is a sectional view for explaining the heat storage 80' of a second modification. In the present modification, the heat storage 80' includes one or more metal plates 71 instead of the metal member 81. For example, the heat storage 80' is formed by the plurality of (for example, two) metal plates 71 being disposed in an overlapping manner in the X direction. Note that the heat storage 80' may be formed by one metal plate 71 or may be formed by three or more metal plates 71. The metal plates 71 are plate members along the Y direction and the Z direction. Each metal plate 71 includes the attachment hole 71h penetrating through the metal plate 71 in the X direction. Since details of the metal plate 71 are the same as the details of the metal plate 71 of the first aspect, repeated description will be omitted.

### 9.2.3 Third Modification

In the aforementioned embodiment, the heat storage 80' is provided for the terminal 23 of the electronic component 20C. Note that the heat storage 80' may be provided for the connection component 30 instead of the terminal 23 of the electronic component 20C. In other words, the heat storage 80' of the third aspect may be provided for the second part 32 of the connection component 30 in the laid posture instead of the heat storage 70Y of the first aspect.

### 9.3 Advantages of Heat Storage of Third Aspect

As a comparative example, an electrical connection unit with no heat storage 80' will be considered. In such a configuration, a significant temperature rise may occur in a part of the electrical connection unit in a case where a large current flows in a short period of time, for example.

Thus, in the present embodiment, the electrical connection unit includes: the base member (for example, the base member 15) that includes the first support surface (for example, the support surface 15s); the connection target component (for example, the electronic component 20 including the terminal 23 or the connection component 30 including the second part 32) that includes the metal plate portion disposed in the upright posture with respect to the first support surface; the routing member (for example, the bus bar 40) that includes the connection portion (for example, the first connection portion 41 or the second connection portion 42) overlapping the metal plate portion when seen from the first direction, which is the plate thickness direction of the metal plate portion, the routing member being electrically connected to the metal plate portion; and the metal member that overlaps the metal plate portion when seen from the first direction. According to such a configuration, a part of heat generated in the electrical connection unit can be stored by the metal member. Alternatively, the heat dissipation area can be increased by the metal member. With this action, it is possible to improve the thermal characteristics (for example, a heat storage property and/or a heat dissipation property) of the electrical connection unit.

Here, it is possible to dispose the electronic component that is long in a specific direction in the laid posture if it is possible to dispose the metal plate portion in the upright posture with respect to the first support surface. With this structure, it is possible to reduce the height of the electrical connection unit. In addition, it is possible to easily expose both surfaces of the metal plate portion to the inside of the electrical connection unit 1 and to easily attach the routing member and the metal member to the metal plate portion if it is possible to dispose the metal plate portion in the upright posture with respect to the first support surface. With this configuration, it is possible to further improve the thermal characteristics (for example, a heat storage property and/or a heat dissipation property) of the electrical connection unit.

In the present embodiment, the routing member includes the extending portion (for example, the extending portion 43) extending along the first support surface. The connection portion of the routing member is formed by a part of the routing member being bent from the extending portion. According to such a configuration, it is possible to use the routing member including the extending portion that extends along the first support surface even in a case where the electronic component that is long in the specific direction is disposed in the laid posture. With this structure, it is possible to miniaturize the electrical connection unit.

In the present embodiment, the metal plate portion includes the first attachment hole (for example, the attachment hole 23h or the attachment hole 32h) penetrating through the metal plate portion in the first direction. The connection portion of the routing member includes the second attachment hole (for example, the attachment hole 40h) facing the first attachment hole. The metal member includes the third attachment hole (for example, the attachment hole 85h) facing the first attachment hole. The connection target component, the routing member, and the metal member are fixed by the fastening member (for example, the fastening member 51) inserted into the first attachment hole, the second attachment hole, and the third attachment hole. According to such a configuration, the connection target component, the routing member, and the metal member can be fixed by a simple fastening structure. With this structure, it is possible to facilitate miniaturization and/or cost reduction of the electrical connection unit.

In the present embodiment, the connection target component is an electronic component. The metal plate portion is a terminal of the electronic component. According to such a configuration, it is possible to easily cause heat to move directly from the terminal of the electronic component to the metal member. With this action, it is possible to further improve the thermal characteristics (for example, a heat storage property and/or a heat dissipation property) of the electrical connection unit.

In the present embodiment, the metal member is a metal block in which the thickness of the metal member in the first direction is equal to or greater than double the thickness of the connection portion of the routing member in the first direction. According to such a configuration, it is possible to easily increase the heat capacity of the heat storage formed by the metal member. With this configuration, it is possible to further improve thermal characteristics (for example, a heat storage property and/or a heat dissipation property) of the electrical connection unit.

In the present embodiment, the metal member is a metal plate along the metal plate portion. Such a metal plate can be obtained at lower cost than the metal block. Therefore, according to the above configuration, it is possible to easily achieve cost reduction of the electrical connection unit while improving the thermal characteristics of the electrical connection unit.

In the present embodiment, the metal member is disposed on the side opposite to the connection portion of the routing member with respect to the metal plate portion. According to such a configuration, it is possible to reduce an energization resistance between the metal plate portion and the connection portion of the routing member as compared with the case where the metal member is disposed between the metal plate portion and the connection portion of the routing member. With this configuration, it is possible to improve electrical characteristics of the electrical connection unit. Also, in a case where the metal member is in contact with the metal plate portion, heat is more likely to move from the metal plate portion to the metal member. With this configuration, it is possible to further improve thermal characteristics (for example, a heat storage property and/or a heat dissipation property) of the electrical connection unit.

Several embodiments and modifications have been described above. However, the embodiments and the modifications are not limited to the examples described above. For example, the configurations of the heat storages 70, 80, and 80X of the first to third aspects described above may be implemented in a mutually combined manner. Also, each of the modifications of the first to third aspects described above may be implemented in a mutually combined manner. The aforementioned embodiments can be implemented in various other forms, and various additions, omissions, substitutions, and modifications can be performed without departing from the gist of the disclosure.

While preferred embodiments of the invention have been described and illustrated above, it should be understood that these are exemplary examples of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

### REFERENCE SIGNS LIST

1 Electrical connection unit

20, 20X, 20Y, 20A, 20B, 20C Electronic component (connection target component)

23 Terminal (metal plate portion)

23h Attachment hole (first attachment hole)

30 Connection component (connection target component)

31 First part

32 Second part (metal plate portion)

32h Attachment hole (first attachment hole)

40 Bus bar (routing member)

40h Attachment hole (second attachment hole)

41 First connection portion

42 Second connection portion

43 Extending portion

51 Fastening member

HS, 70, 70X, 70Y, 80, 80' Heat storage

71 Metal plate

71A First metal plate

71B Second metal plate

71h Attachment hole (third attachment hole)

81 Metal member

85 Block body

86 Hole

85a Base portion

85b Peripheral wall portion

85c Space portion

85h Attachment hole (third attachment hole)

What is claimed is:

1. An electrical connection unit comprising:
a base member that includes a first support surface;
a connection target component that includes a metal plate portion disposed in an upright posture with respect to the first support surface;
a routing member that includes a connection portion overlapping the metal plate portion when seen from a first direction, which is a plate thickness direction of the metal plate portion, the routing member being electrically connected to the metal plate portion; and
a metal member that overlaps the metal plate portion when seen from the first direction.

2. The electrical connection unit according to claim 1, wherein
the routing member includes an extending portion that extends along the first support surface, and
the connection portion of the routing member is formed by a part of the routing member being bent from the extending portion.

3. The electrical connection unit according to claim 1, wherein
the metal plate portion includes a first attachment hole that penetrates through the metal plate portion in the first direction,
the connection portion of the routing member includes a second attachment hole that faces the first attachment hole,
the metal member includes a third attachment hole that faces the first attachment hole, and
the connection target component, the routing member, and the metal member are fixed by a fastening member inserted into the first attachment hole, the second attachment hole, and the third attachment hole.

4. The electrical connection unit according to claim 1, wherein
the connection target component is an electronic component, and
the metal plate portion is a terminal of the electronic component.

5. The electrical connection unit according to claim 1, wherein
the metal member is a metal block in which a thickness of the metal member in the first direction is equal to or greater than double a thickness of the connection portion of the routing member in the first direction.

6. The electrical connection unit according to claim 1, wherein
the metal member is a metal plate along the metal plate portion.

7. The electrical connection unit according to claim 1, wherein
the metal member is disposed on a side opposite to the connection portion of the routing member with respect to the metal plate portion.
